(19) United States
(12) Patent Application Publication
(10) Pub. No.: US 2026/0150255 A1
(43) Pub. Date: May 28, 2026

(54) ELECTRONIC DEVICE

(71) Applicant: CANAAN CREATIVE CO.,LTD., Beijing (CN)

(72) Inventors: Shaohua ZHANG, Beijing (CN); Nangeng ZHANG, Beijing (CN)

(21) Appl. No.: 19/121,670

(22) PCT Filed: Oct. 20, 2023
(86) PCT No.: PCT/CN2023/125718

§ 371 Date: Apr. 16, 2025

(30) Foreign Application Priority Data
Oct. 20, 2022 (CN) 202211287134.7
May 12, 2023 (CN) 202310539625.4

(51) Int. Cl. H05K 7/20

(52) U.S. Cl. CPC H05K 7/20972; H05K 7/20963

(57) ABSTRACT

An electronic device. The electronic device comprises: a housing, wherein a heat-dissipating air duct with an air inlet and an air outlet is defined within the housing, and at least one working assembly is disposed in the heat-dissipating air duct; and a control board disposed above the housing and electrically connected to an upper end of the working assembly. It is more convenient to install and disassemble the working assembly, and the efficiency of servicing and replacement of the working assembly may be effectively improved.

### CROSS REFERENCE TO RELATED APPLICATIONS

This present application is a U.S. National Stage Application of International Application No. PCT/CN2023/125718, filed on Oct. 20, 2023, which claims priority to and benefits of Chinese Patent Application No. 202211287134.7, titled “ELECTRONIC DEVICE”, filed with the China National Intellectual Property Administration on Oct. 20, 2022, and Chinese Patent Application No. 202310539625.4, titled “ELECTRONIC DEVICE”, filed with the China National Intellectual Property Administration on May 12, 2023. The entire contents of all of the above-identified applications are incorporated herein by reference.

### TECHNICAL FIELD

The present application relates to the field of heat dissipation technology, and in particular to an electronic device.

### BACKGROUND

In the related art, a computing device is usually provided with a plurality of working assemblies.

### SUMMARY

Embodiments of the present application provide an electronic device.

As one aspect of the embodiments of the application, the present application provides in its embodiments an electronic device. The electronic device includes: a housing, wherein a heat-dissipating air duct with an air inlet and an air outlet is defined within the housing, and at least one working assembly is disposed in the heat-dissipating air duct; and a control board disposed above the housing and electrically connected to an upper end of the working assembly.

In one implementation, the electronic device further includes: at least one fan module arranged on a side of the housing in an arrangement direction of the air inlet and the air outlet; wherein at least one fan interface is disposed on the control board, and the fan interface is connected to the fan module.

In one implementation, at least one fan interface is disposed close to the fan module.

In one implementation, the working assembly includes a circuit board.

In one implementation, the working assembly includes a heat sink, and the heat sink is disposed on at least a side of the circuit board.

In one implementation, a first signal socket is provided on the circuit board, a second signal socket is provided on the control board, and the first signal socket is electrically connected to the second signal socket.

In one implementation, the second signal socket is arranged on a side of the control board close to the first signal socket.

In one implementation, the electronic device further includes: a power supply module disposed on a side of the housing and configured to supply power to the working assembly; wherein the control board is provided with a power supply interface, which is connected to the power supply module.

In one implementation, the power supply interface is disposed on a side of the control board close to the power supply module.

In one implementation, the working assembly includes a circuit board, and the circuit board is provided with a first connection base and a second connection base; wherein the first connection base includes a first connection portion connected to the circuit board and a first connection base body connected to the power supply module; the second connection base includes a second connection portion connected to the circuit board and a second connection base body connected to the power supply module.

In one implementation, a through hole is provided on the first connection portion and/or the second connection portion.

In one implementation, the electronic device further includes: a first conductive connection member connected between the first connection base body and the power supply module; and a second conductive connection member connected between the second connection base body and the power supply module.

In one implementation, the first conductive connection member includes a first circuit board connection portion and a first power supply connection portion, the first circuit board connection portion is connected to the first connection base body, and the first power supply connection portion is connected to the power supply module; the second conductive connection member includes a second circuit board connection portion and a second power supply connection portion, the second circuit board connection portion is connected to the second connection base body, and the second power supply connection portion is connected to the power supply module.

In one implementation, the first circuit board connection portion and/or the second circuit board connection portion extend in a direction that is perpendicular to a direction from the air inlet to the air outlet and perpendicular to a vertical direction.

In one implementation, the control board is provided with an indicator light, which is located at an end of the control board close to a side of the air inlet or the air outlet.

In one implementation, a top housing is disposed on the top of the housing, and the control board is disposed in the top housing.

In one implementation, the control board is provided with a temperature sensor.

In one implementation, the temperature sensor is disposed at the bottom of the control board, the temperature sensor is located within the top housing, and a top surface of the housing is formed with a ventilation hole in communication with the heat-dissipating air duct, and the ventilation hole corresponds to the temperature sensor in position.

In one implementation, the temperature sensor is disposed on the top of the control board, and the temperature sensor protrudes from a side surface of the top housing.

In one implementation, a free end of the temperature sensor passes through the top of the housing and protrudes into the housing.

In one implementation, the electronic device further includes: a mounting member connected to the housing; wherein the fan module is connected to a side of the mounting member facing away from the housing.

In one implementation, there are two fan modules arranged in a vertical direction.

In one implementation, the two fan modules arranged in the vertical direction constitute a fan group, and there are a plurality of fan groups disposed in a direction from the air inlet to the air outlet.

In one implementation, first mounting portions are disposed at four corners of the fan module, second mounting portions are provided on the mounting member, and fasteners respectively pass through the first mounting portions to be connected to corresponding second mounting portions.

In one implementation, the first mounting portions are through holes, the second mounting portions are threaded holes, and the fasteners are threaded fasteners.

In one implementation, a flexible protective cover is provided on a side of the fan module facing away from the mounting member, and the flexible protective cover is sleeved on an outer periphery of the fan module.

The above summary is for the purpose of illustration only and is not intended to be limiting in any way. In addition to the schematic aspects, implementations and features described above, further aspects, implementations and features of the present application will readily apparent by referring to the accompanying drawings and the following detailed description.

### BRIEF DESCRIPTION OF THE DRAWINGS

In the drawings, unless otherwise specified, the same reference numerals refer to identical or similar parts or elements throughout the drawings. These drawings are not necessarily drawn to scale. It should be understood that these drawings only depict some implementations disclosed in accordance with the present application and should not be considered as limiting the scope of the present application.

FIG. 1 is a schematic perspective structural diagram of an electronic device according to an embodiment of the present application;

FIG. 2 is a perspective view of the electronic device shown in FIG. 1 from another perspective;

FIG. 3 is a front view of the electronic device shown in FIG. 1;

FIG. 4 is a rear view of the electronic device shown in FIG. 1;

FIG. 5 is a left view of the electronic device shown in FIG. 1;

FIG. 6 is a right view of the electronic device shown in FIG. 1;

FIG. 7 is a top view of the electronic device shown in FIG. 1;

FIG. 8 is a bottom view of the electronic device shown in FIG. 1;

FIG. 9A is an exploded view of the electronic device shown in FIG. 1;

FIG. 9B is an enlarged view of the circled portion A in FIG. 9A;

FIG. 10A is a schematic structural diagram of a ventilation panel according to another embodiment of the present application;

FIG. 10B is a partial enlarged view of the ventilation panel shown in FIG. 10A;

FIG. 11 is another exploded view of the electronic device shown in FIG. 1;

FIG. 12 is a schematic diagram of installing a fan assembly of the electronic device shown in FIG. 1;

FIG. 13 is a sectional view of the electronic device shown in FIG. 1;

FIG. 14 is a schematic diagram of cable connection of a fan module of the electronic device shown in FIG. 1;

FIG. 15 is a perspective view of a fan assembly of the electronic device shown in FIG. 1;

FIG. 16 is an enlarged view of the circled portion B in FIG. 15;

FIG. 17 is a perspective view of a fan assembly of the electronic device shown in FIG. 1 from another perspective;

FIG. 18 is a perspective view of a mounting member of the fan assembly shown in FIG. 17;

FIG. 19 is a perspective view of a flexible protective cover of the fan assembly shown in FIG. 17;

FIG. 20 is a schematic diagram of the internal structure of the electronic device shown in FIG. 1;

FIG. 21 is a schematic diagram of cable connection of the electronic device shown in FIG. 1;

FIG. 22 is a schematic structural diagram of a first conductive connection member and a second conductive connection member according to an embodiment of the present application;

FIG. 23 is a sectional view of an electronic device according to an embodiment of the present application;

FIG. 24 is an enlarged view of the circled portion C in FIG. 23;

FIG. 25A is a sectional view of an electronic device according to an embodiment of the present application;

FIG. 25B is an enlarged view of the circled portion D in FIG. 25A;

FIG. 26A is a sectional view of an electronic device according to an embodiment of the present application;

FIG. 26B is a partial enlarged view of the electronic device shown in FIG. 26A;

FIG. 27 is a schematic installation diagram of a power supply module according to an embodiment of the present application;

FIG. 28 is a schematic installation diagram of a power supply module from another perspective according to an embodiment of the present application;

FIG. 29A is a schematic diagram of the connection between a power supply module and a housing according to an embodiment of the present application;

FIG. 29B is an enlarged view of the circled portion E in FIG. 29A;

FIG. 30A is a schematic installation diagram of a power supply module of an electronic device according to another embodiment of the present application;

FIG. 30B is a partial enlarged view of the electronic device shown in FIG. 30A;

FIG. 30C is a schematic structural diagram of a threaded fastener of the electronic device shown in FIG. 30A;

FIG. 31 is a schematic perspective structural diagram of a working assembly according to an embodiment of the present application;

FIG. 32 is a perspective view of the working assembly shown in FIG. 31 from another perspective;

FIG. 33 is a front view of the working assembly shown in FIG. 31;

FIG. 34 is a rear view of the working assembly shown in FIG. 31;

FIG. 35 is a left view of the working assembly shown in FIG. 31;

FIG. 36 is a right view of the working assembly shown in FIG. 31;

FIG. 37 is a top view of the working assembly shown in FIG. 31;

FIG. 38 is a bottom view of the working assembly shown in FIG. 31; and

FIG. 39A is an exploded view of the working assembly shown in FIG. 31;

FIG. 39B is a schematic diagram of a working assembly according to another embodiment of the present application;

FIG. 40 is a schematic structural diagram of a first connection base of a working assembly according to an embodiment of the present application;

FIG. 41 is a schematic structural diagram of a first connection base of a working assembly according to an embodiment of the present application;

FIG. 42 is a schematic partial structural diagram of a sealing member of a working assembly according to an embodiment of the present application;

FIG. 43 is a schematic mounting diagram of a sealing member of a working assembly according to an embodiment of the present application;

FIG. 44 is a schematic structural diagram of a spring screw of a working assembly according to an embodiment of the present application;

FIG. 45 is a schematic perspective structural diagram of a working assembly according to another embodiment of the present application;

FIG. 46 is a front view of the working assembly shown in FIG. 45;

FIG. 47 is a rear view of the working assembly shown in FIG. 45;

FIG. 48 is a left view of the working assembly shown in FIG. 45;

FIG. 49 is a right view of the working assembly shown in FIG. 45;

FIG. 50 is a top view of the working assembly shown in FIG. 45;

FIG. 51 is a bottom view of the working assembly shown in FIG. 45; and

FIG. 52 is a schematic structural diagram of a circuit board according to an embodiment of the present application.

Notes of reference numerals:

100: working assembly;

110: circuit board; 111: heat-generating component; 112: first signal socket; 120: heat sink; 121: heat sink body; 122: heat sink fin; 1221: beveled portion; 1222: groove; 123: first heat sink; 124: second heat sink; 140: first connection base; 141: first connection portion; 1411: flanging; 1412: first through hole; 142: first connection base body; 143: avoidance slot; 150: second connection base; 151: second connection portion; 152: second connection base body; 160: sealing member; 161: first sealing portion; 162: second sealing portion; 170: spring screw; 171: spring; 172: screw;

200: electronic device;

210: housing; 211: ventilation hole; 212: top housing; 213: ventilation panel; 2131: ventilation body; 2132: ventilation side plate; 2133: ventilation top plate; 2134: ventilation bottom plate; 2135: second bent portion; 2136: spacing slot; 2137: second ventilation hole; 214: second elastic clip; 215: second conductive foam; 220: fan assembly; 221: mounting member; 2211: threaded hole; 2212: fixing hole; 2213: mounting body; 2214: mounting side plate; 2215: mounting top plate; 2216: mounting bottom plate; 2217: first bent portion; 2218: reinforcing rib; 2219: via hole; 2220: first ventilation hole; 221a: third ventilation hole; 222: fan module; 230: first elastic clip; 231: connection portion; 232: abutment portion; 240: first conductive foam; 250: flexible protective cover; 260: control board; 261: second signal socket; 262: fan interface; 263: temperature sensor; 264: indicator light; 265: power supply interface; 270: power supply module; 271: positioning hole; 272: second through hole; 273: threaded fastener; 280: first conductive connection member; 281: first circuit board connection portion; 282: first power supply connection portion; 290: second conductive connection member; 291: second circuit board connection portion; 292: second power supply connection portion.

### DETAILED DESCRIPTION

Hereinafter, certain exemplary embodiments are described briefly. As those skilled in the art will recognize, the described embodiments may be modified in various different ways without departing from the spirit or scope of the present application. Accordingly, the drawings and description are to be regarded as illustrative in nature and not restrictive.

A computing device is usually provided with a plurality of working assemblies. In the case of servicing or replacing the working assemblies, the operation is relatively cumbersome, which reduces the efficiency of servicing and replacement of the working assemblies.

By adopting the technical solutions disclose herein, the embodiments of the present application may enable the installation and disassembly of the working assembly more convenient, and can effectively improve the efficiency of servicing and replacement of the working assembly.

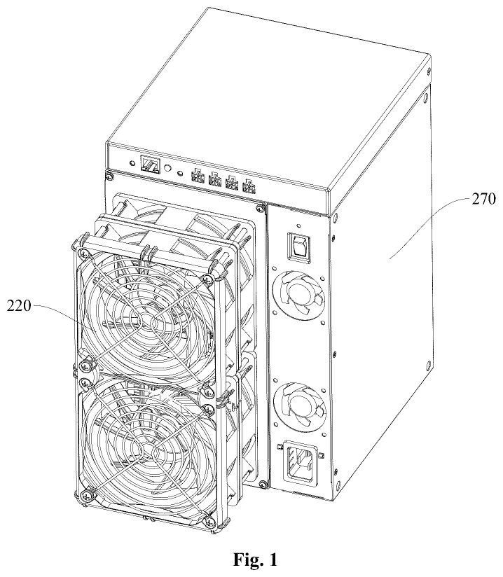

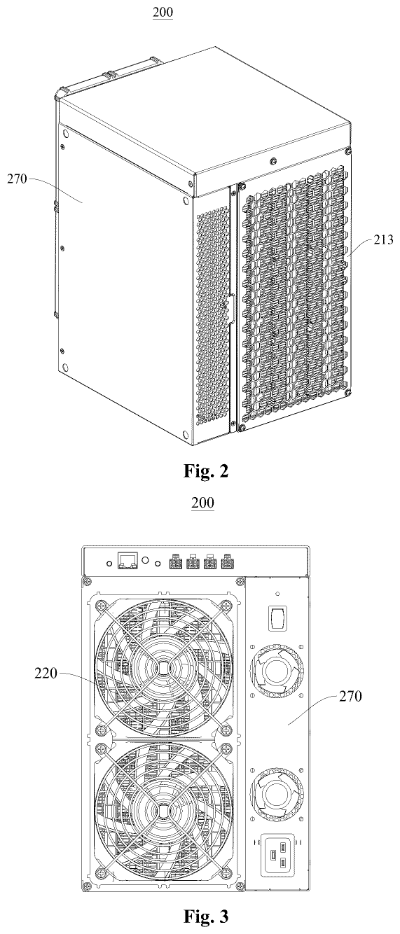

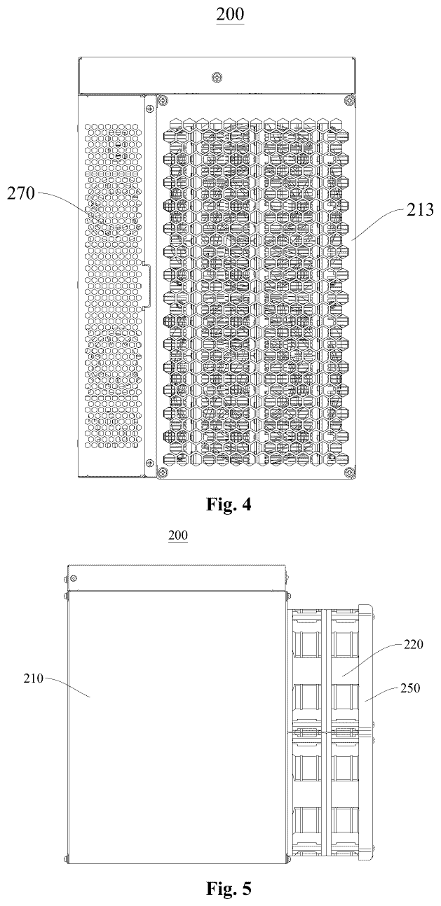

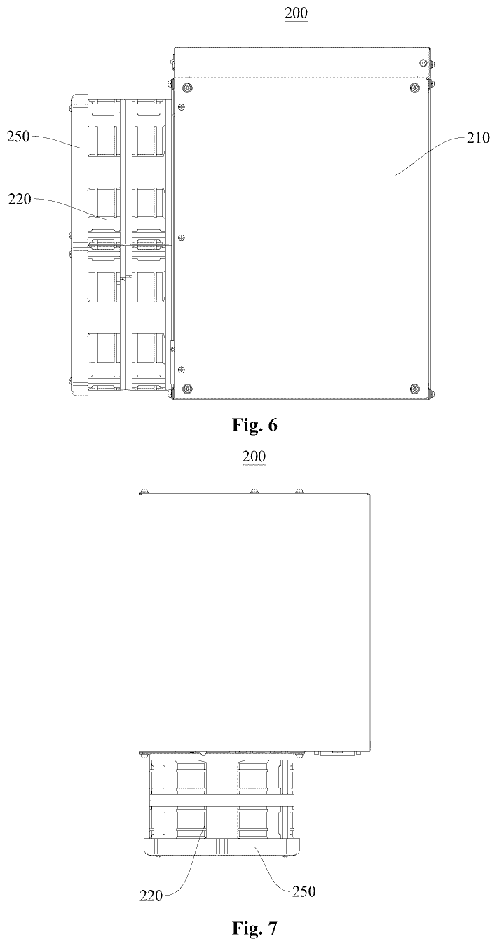

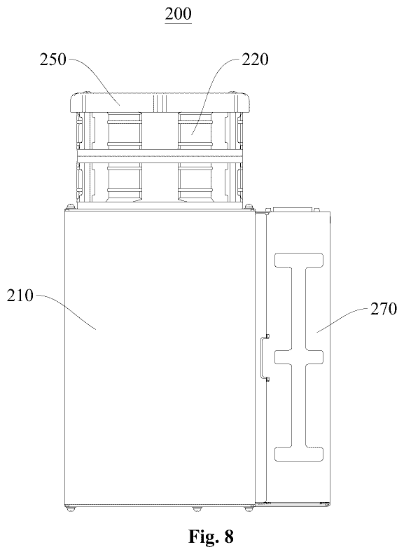

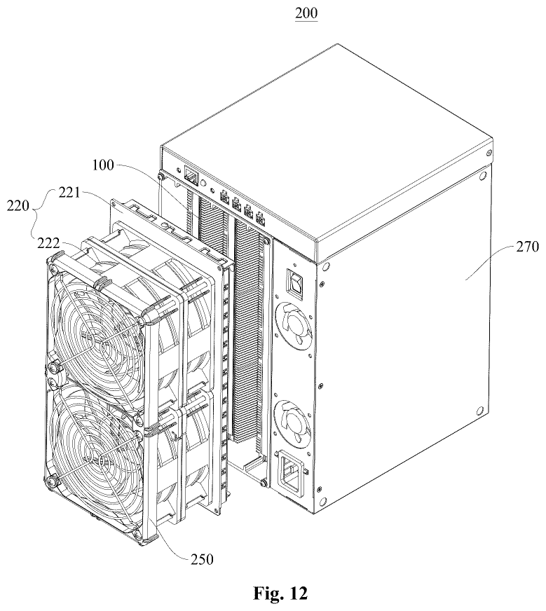

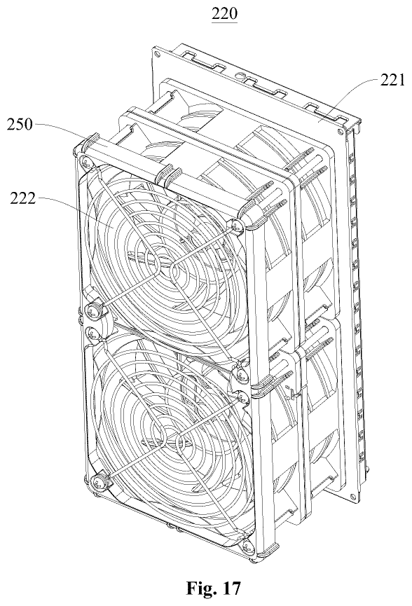

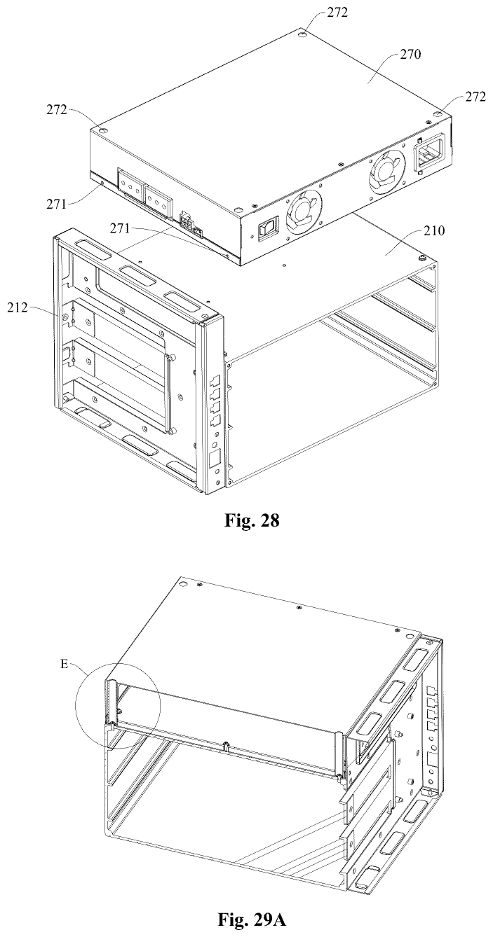

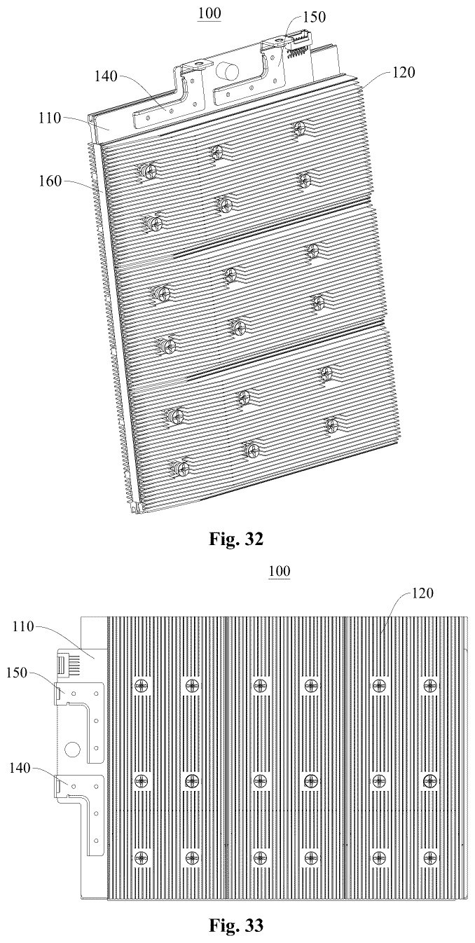

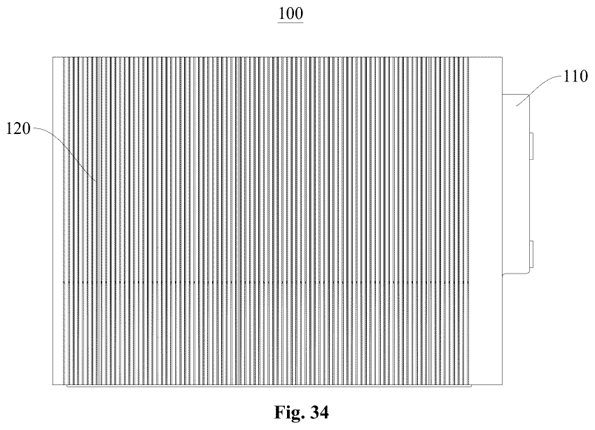

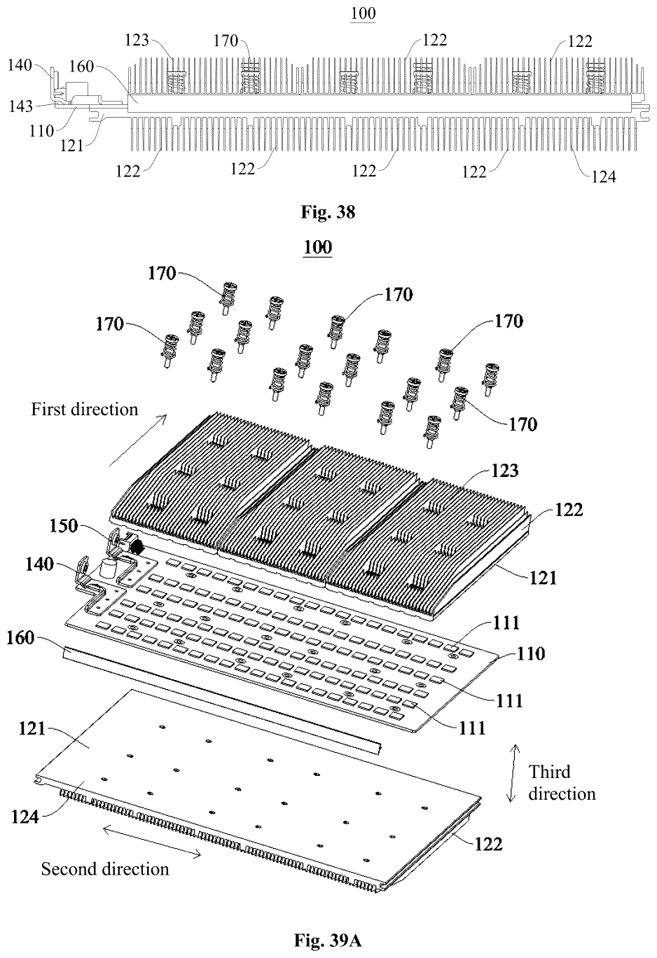

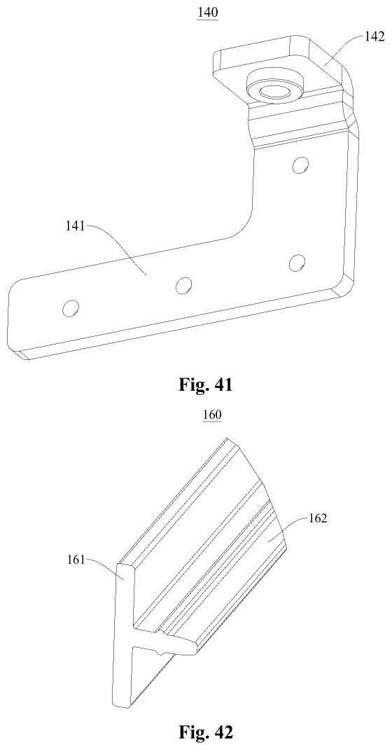

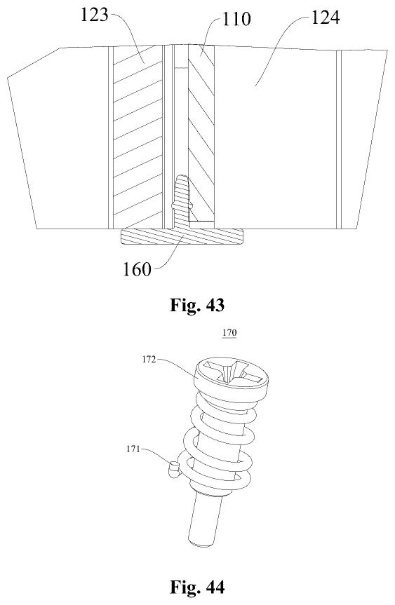

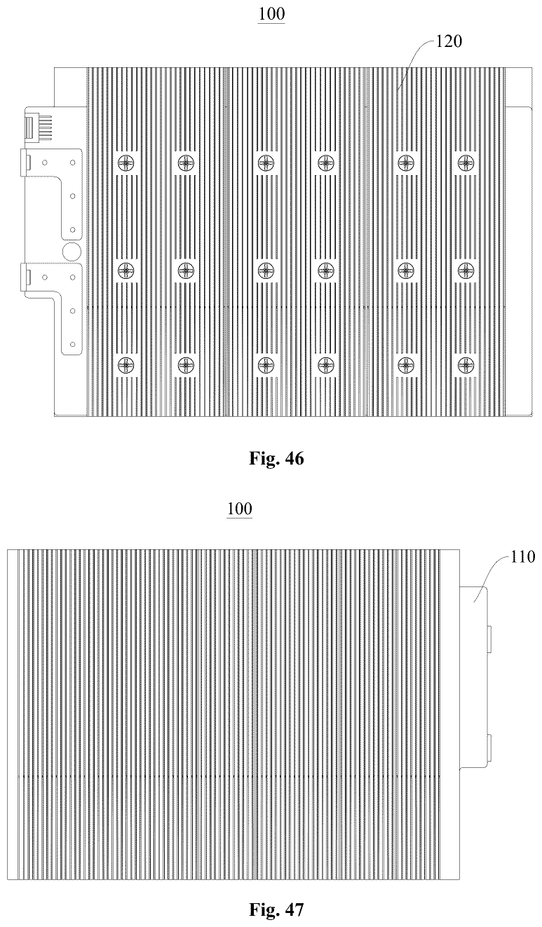

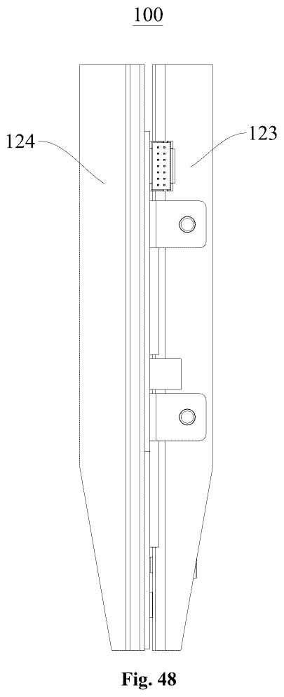

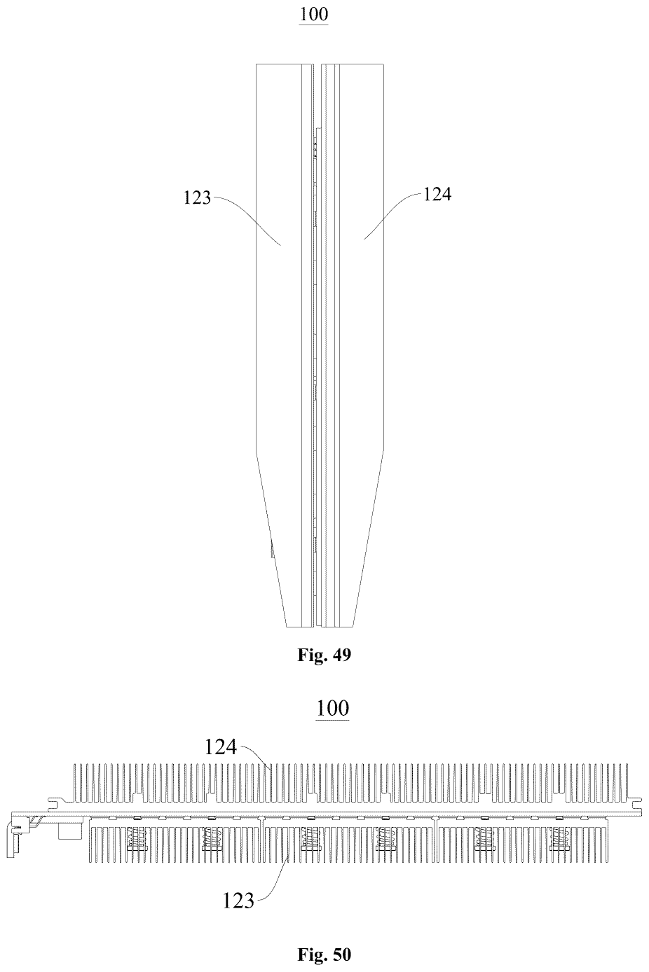

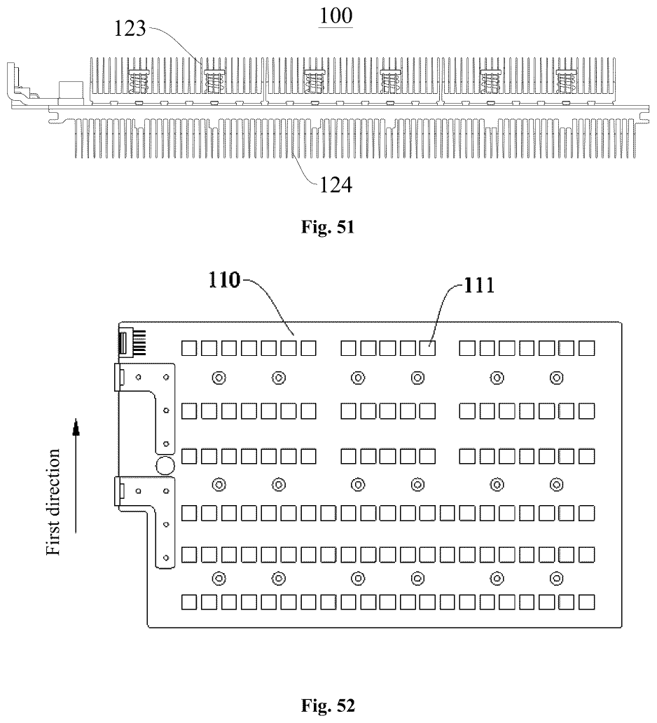

A working assembly 100 according to a first aspect of the embodiments of the present application is described below in conjunction with FIGS. 1-52. The working assembly 100 is suitable for working in a heat-dissipating air duct to achieve heat dissipation of the working assembly 100.

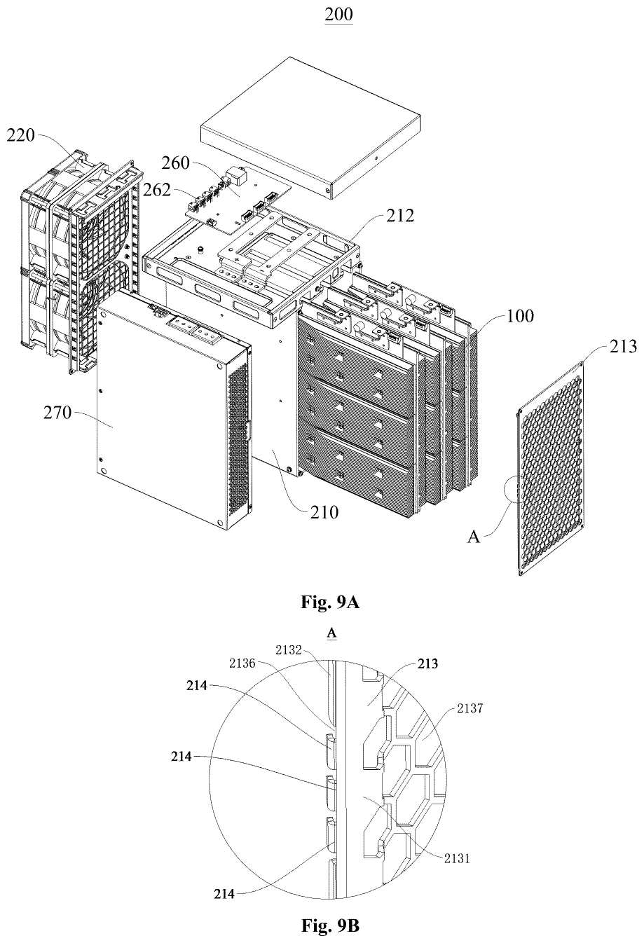

As shown in FIGS. 9 and 31-39A, the working assembly 100 includes a circuit board 110 and at least one heat sink 120. Specifically, a plurality of heat-generating components 111 are disposed on at least one side surface of the circuit board 110, and the heat sink 120 is disposed on the circuit board 110. In the description of the present application, “a plurality of” means two or more.

For example, two heat sinks 120 are shown in the examples of FIGS. 31-39A, and the two heat sinks 120 are respectively a first heat sink 123 and a second heat sink 124. The first heat sink 123 is disposed on a first surface of the circuit board 110, and the second heat sink 124 is disposed on a second surface of the circuit board 110. The plurality of heat-generating components 111 may include a plurality of chips disposed on the first surface of the circuit board 110, the first heat sink 123 may be disposed corresponding to the chips, and the first heat sink 123 may be in contact with the chips directly or indirectly through a thermally conductive material (such as silicone grease). The first heat sink 123 is provided with a plurality of bosses, which are disposed corresponding to the chips. The bosses may be disposed in a plurality of rows or columns, with each row of a plurality of rows of bosses corresponding to each row of chips; each column of a plurality of columns of bosses corresponding to each column of chips. The bosses may also be an array of independent structures, with each independent boss corresponding to a single chip, and the cross-sectional area of each independent boss may cover a single chip or be smaller than a single chip. The first heat sink 123 may include a plurality of independently disposed sub-heat sinks.

The heat on the first surface of the circuit board 110 may be effectively conducted to the first heat sink 123, and the heat on the second surface of the circuit board 110 may be effectively conducted to the second heat sink 124. In the process of air blowing from the air inlet to the air outlet of the heat-dissipating air duct, the heat of the first heat sink 123 and the second heat sink 124 may be effectively taken away, thereby achieving effective heat dissipation of the circuit board 110.

Although two heat sinks 120 are shown in FIGS. 31-39A for illustrative purposes, after reading the technical solution of the present application, a person of ordinary skill in the art will clearly understand that the solution may be applied to technical solutions involving one heat sink or more than two heat sinks 120, and such applications also fall within the scope of protection of the present application.

At the air outlet of the heat-dissipating air duct, the size of at least one heat sink 120 in the first direction is larger than the size of the circuit board 110 in the first direction, and the first direction is a direction from the air inlet to the air outlet of the heat-dissipating air duct. An edge of at least one heat sink 120 close to the air outlet exceeds an edge of the circuit board 110 close to the air outlet.

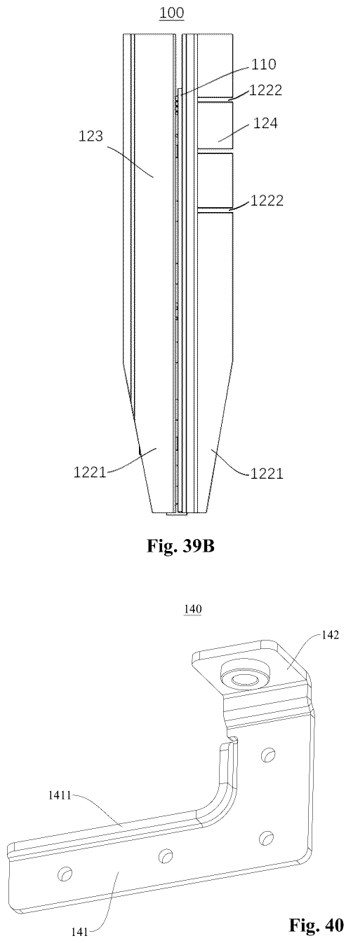

Illustratively, the first and second surfaces of the circuit board 110 may both be parallel to the first direction. The plurality of heat-generating components 111 on the first surface may be disposed in rows, and in the first direction, the centers of at least three or all of the heat-generating components 111 are in a straight line. The plurality of heat-generating components 111 on the first surface may be disposed in columns, and in the second direction, the centers of at least three or all of the heat-generating components 111 are in a straight line, and the second direction is perpendicular to the first direction. FIG. 39A shows six columns of heat-generating components 111. The six columns of heat-generating components 111 may be divided into two parts, and each part includes three columns of heat-generating components 111. One of the two parts is disposed close to the air inlet, and the other of the two parts is disposed close to the air outlet. The edges of the first heat sink 123 and the second heat sink 124 close to the air outlet may both extend beyond the edge of the circuit board 110 close to the air outlet. With such a configuration, it may increase the area of the heat sink 120 at the air outlet, so that the heat of a group of heat-generating components 111 close to the air outlet can be better conducted to the corresponding heat sink 120, reducing the maximum temperature difference between the three columns of heat-generating components 111 close to the air outlet. At the same time, the heat dissipation effect of the three columns of heat-generating components 111 close to the air outlet can be improved, which is beneficial to reducing the maximum temperature difference between the two groups of heat-generating components 111, thereby improving the overall temperature uniformity of the plurality of heat-generating components 111.

The working assembly 100 according to the embodiments of the present application may lengthen the size of the at least one heat sink 120 close to the air outlet in the first direction, thereby reducing the maximum temperature difference between the heat-generating components 111 close to the air outlet and the heat-generating components 111 close to the air inlet, thereby improving the temperature uniformity of the heat-generating components 111.

In one implementation, along the first direction, the size of the heat sink 120 exceeds the size of the circuit board 110 by 10 mm to 20 mm (inclusive). Specifically, for example, the size of the heat sink 120 exceeds the size of the circuit board 110 by L. When L is less than 10 mm, at the air outlet of the heat-dissipating air duct, the size of the heat sink 120 exceeding the circuit board 110 in the first direction is too small, resulting in poor heat dissipation effect of the heat-generating components 111 close to the air outlet, and the temperature uniformity of the heat-generating components 111 cannot be effectively improved; when L is greater than 20 mm, the size of the heat sink 120 exceeding the circuit board 110 in the first direction is too large, and the space occupied by the heat sink 120 at the air outlet is too large, which will increase the volume of the housing 210 and cause the weight of the heat sink 120 to be too heavy.

Therefore, by ensuring that 10 mm≤L≤20 mm, the size of the portion of the heat sink 120 exceeding the end of the circuit board 110 close to the air outlet is reasonable, which can effectively improve the temperature uniformity of the heat-generating components 111 while reducing the overall space occupied by the working assembly 100, and avoid excessive weight of the working assembly 100. Optionally, L may be 15 mm, but is not limited thereto. Those skilled in the art will understand that “the size of the heat sink 120 exceeds the size of the circuit board 110 by L”, and L is not limited to the above range of 10 mm≤L≤20 mm. When there is a need to improve the heat dissipation of the rear half of the circuit board or the heat-generating source, the method of extending the length of the heat sink in the present invention can be applied to adaptively adjust the length L according to different usage scenarios.

In one implementation, in combination with FIGS. 39A and 39B, each heat sink 120 includes a heat sink body 121 and a plurality of heat sink fins 122 disposed on the heat sink body 121, the heat sink body 121 is parallel to the circuit board 110, the heat sink fins 122 are perpendicular to the circuit board 110, and at least one of heat sink fins 122 is formed with at least one groove 1222.

In an example, each groove 1222 may penetrate a corresponding heat sink fin 122 in the second direction and a third direction to divide the heat sink fin 122 into a plurality of sub-heat sink fins. The calculation formula of the convection thermal resistance between the heat sink fin 122 and the air environment is: R=1/(hA), where R is the convection thermal resistance between the heat sink fin and the air environment, h is the convection heat transfer coefficient, and A is the heat dissipation area. The groove 1222 may divide the entire heat sink 122 into a plurality of sub-heat sinks spaced apart in the first direction. The air will expand and then contract in flowing through this area. After the air passes through the groove 1222 area, the disturbance becomes stronger, the convection heat transfer coefficient becomes larger, and the thermal resistance is reduced.

In an example, the at least one groove 1222 does not penetrate the corresponding heat sink fin 122 in the second direction and/or the third direction. At this time, each heat sink fin 122 is not divided into a plurality of sub-fins. The second direction is a direction in which the plurality of heat sink fins 122 are arranged, and the third direction is a direction perpendicular to the surface of the circuit board 110.

Therefore, by disposing the above-mentioned groove 1222, the overall weight of the heat sink 122 can be reduced, and the air resistance of air flowing through the heat sink 120 may be effectively reduced, the ventilation volume can be increased, and the dust accumulation on the heat sink 122 can be reduced while improving the heat-dissipating effect. Specifically, the amount of dust accumulated on the side of the heat sink 120 close to the air inlet is generally greater than the amount of dust accumulated on the side close to the air outlet. In the case where the groove 1222 is disposed at an end of the heat sink fin 122 close to the air inlet, the amount of dust accumulated at the end of the heat sink 120 close to the air inlet may be further increased. By disposing the groove 1222 at an end of the heat sink fin 122 close to the air outlet, it is possible to avoid increasing the amount of dust accumulation at the air inlet of the heat sink 120 and improve the local heat dissipation effect of the heat sink 120.

In one implementation, the groove 1222 is disposed at an end of the heat sink 122 closer to the air outlet relative to the center of the heat sink 120, that is, “the end closer to the air outlet” refers to the end closer to the air outlet with the center of the heat sink 120 as a reference standard. Therefore, since the temperature of the air at the air outlet is usually high, after the air exchanges heat with the end of the heat sink 120 close to the air outlet, the heat generated by the heat-generating components 111 in the working process cannot be effectively taken away. By disposing the groove 1222 close to the air outlet, the convection heat transfer coefficient of the air outlet area can be increased, and the thermal resistance at the air outlet can be reduced, thereby increasing the ventilation volume at the air outlet, improving the heat dissipation effect of the heat-generating components 111 at the air outlet, while also suppressing the deposition of dust, further improving the temperature uniformity of the heat-generating components 111.

In one implementation, the groove 1222 is disposed corresponding to the heat-generating components 111. Illustratively, the heat sink fins 122 of the at least one heat sink 120 are all provided with a groove 1222, a plurality of grooves 1222 are disposed in columns, and at least one column of grooves 1222 is disposed opposite to at least one column of heat-generating components 111. For example, the grooves 1222 on the plurality of heat sink fins 122 may correspond to each other in the direction in which the heat sink fins 122 are arranged, so that the grooves 1222 on the plurality of heat sink fins 122 are disposed in columns. It is possible that only the heat sink fins 122 of the first heat sink 123 are provided with grooves 1222, as shown in FIG. 39B; or only the heat sink fins 122 of the second heat sink 124 are provided with grooves 1222. It is also possible that both the heat sink fins 122 of the first heat sink 123 and the second heat sink 124 are provided with grooves 1222, in which case the grooves 1222 on the heat sink fins 122 of the first heat sink 123 and the second heat sink 124 may be different.

Optionally, the size of the groove 1222 in the first direction may be 2.5 mm to 3.5 mm (inclusive). However, it is not limited to this range. For example, when the size of the groove 1222 in the first direction is less than 2.5 mm, the width of the groove 1222 is too small, which may reduce the weight reduction effect. When the size of the groove 1222 in the first direction is greater than 3.5 mm, the width of the groove 1222 is too large, which may cause the surface area of the heat sink 122 to be too small, thereby reducing the heat dissipation effect. By enabling the size of the groove 1222 in the first direction to be 2.5 mm to 3.5 mm, the weight of the heat sink 120 may be effectively reduced while ensuring the heat dissipation effect of the heat sink 120.

Illustratively, along the first direction, the size of the groove 1222 on each heat sink fin 122 may gradually increase; or along the first direction, the size of the groove 1222 on each heat sink fin 122 may gradually decrease; or along the first direction, the size of the groove 1222 on each heat sink fin 122 may be completely equal. It is also possible that the size of the groove 1222 is positively or negatively correlated with the width of the heat sink fin 122. Of course, the present application is not limited thereto. For example, the groove 1222 on each heat sink fin 122 may be sized as needed, in combination with the variation in the width of the heat sink fin between two adjacent grooves 1222. It will be understood that the size, number, and specific position of the grooves 1222 on the heat sink fins 122 may be specifically set according to actual needs to better meet practical applications.

Therefore, by making the grooves 1222 correspond to the heat-generating components 111 in position, the heat generated in the working process by the heat-generating components 111 opposite to the grooves 1222 can be conducted to the heat sink body 121, and the air flowing through the heat sink body 121 can directly exchange heat with the heat sink body 121 to achieve heat dissipation of the heat-generating components 111. Since the convection heat transfer coefficient at the groove 1222 is large, the air resistance may be effectively reduced, thereby increasing the air volume at the heat-generating components 111 opposite to the grooves 1222 and improving the heat dissipation effect of the heat-generating components 111 opposite to the grooves 1222.

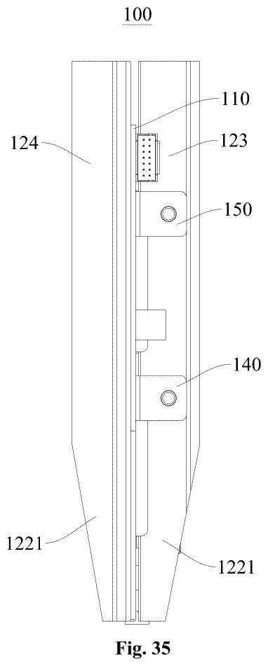

In one implementation, in combination with FIGS. 35, 36 and 39A, the at least one heat sink fin 122 includes a beveled section 1221, and a height of the beveled section 1221 gradually increases along the first direction.

In one implementation, an end of the beveled section 1221 away from the air inlet corresponds to the position of a third column of heat-generating components 111. The above-mentioned “third column of heat-generating components 111” refer to the heat-dissipating components located in the third column along the first direction. For example, in the examples of FIGS. 35, 36 and 39A, all the heat sink fins 122 of the first heat sink 123 and the second heat sink 124 include a beveled section 1221, and the beveled section 1221 is disposed close to the air inlet. Six columns of heat-generating components 111 are disposed on the circuit board 110. Along the first direction, the first three columns of heat-generating components 111 may be disposed opposite to the beveled section 1221, and the last three columns of heat-generating components 111 may be disposed opposite to the corresponding grooves 1222.

Therefore, by disposing the above-mentioned beveled section 1221, the weight of the entire heat sink fin 122 may be effectively reduced, and the thermal resistance at the air inlet can be reduced, thereby increasing the ventilation volume at the air inlet, and improving the heat dissipation effect of the heat-generating components 111 at the air inlet, while also suppressing the deposition of dust and improving the temperature uniformity of the heat-generating components 111.

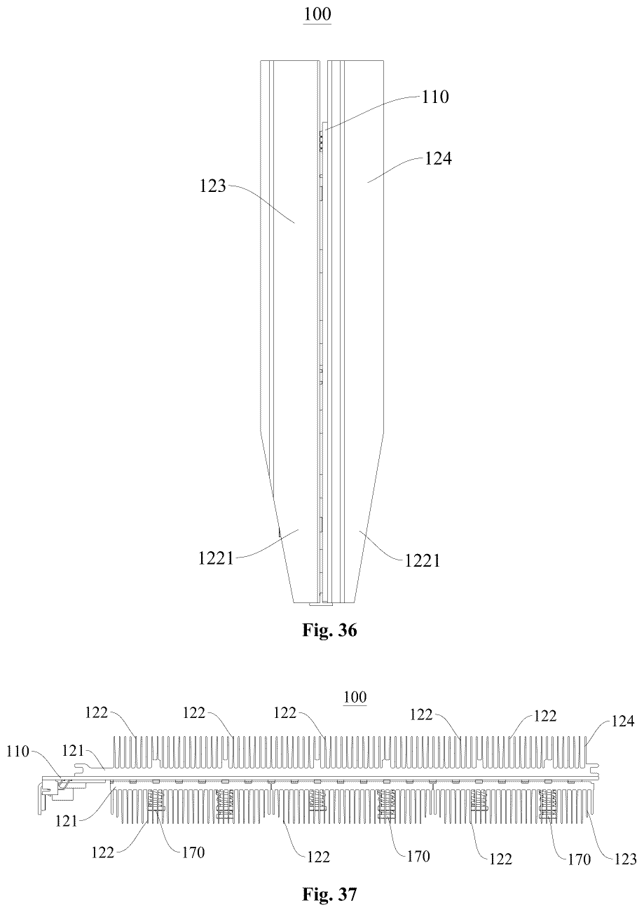

In one implementation, as shown in FIGS. 35 and 36, along the first direction, the size of the first heat sink 123 is the same as the size of the second heat sink 124. With such an arrangement, while heat dissipation of the first surface and the second surface of the circuit board 110 is achieved, the sizes of the first heat sink 123 and the second heat sink 124 may be consistent, thereby improving the versatility of the heat sink 120 and facilitating the processing of the heat sink 120.

In one implementation, the density of the heat sink fins 122 of the first heat sink 123 is the same as the density of the heat sink fins 122 of the second heat sink 124, and the height of the heat sink fins 122 of the first heat sink 123 is different from the height of the heat sink fins 122 of the second heat sink 124. For example, the height of the heat sink fins 122 of the first heat sink 123 may be greater than the height of the heat sink fins 122 of the second heat sink 124. Since the first heat sink 123 is in contact with a plurality of heat-generating components 111, by making the height of the heat sink fins 122 of the first heat sink 123 greater than the height of the heat sink fins 122 of the second heat sink 124, the area of the heat sink fins 122 of the first heat sink 123 may be greater than the area of the heat sink fins 122 of the second heat sink 124. Thus, the heat sink fins 122 of the first heat sink 123 can effectively absorb the heat generated by the plurality of heat-generating components 111 in the working process, thereby improving the heat dissipation effect.

In one implementation, the height of the heat sink fins 122 of the first heat sink 123 is the same as the height of the heat sink fins 122 of the second heat sink 124, and the density of the heat sink fins 122 of the first heat sink 123 is different from the density of the heat sink fins 122 of the second heat sink 124. For example, the density of the heat sink fins 122 of the first heat sink 123 may be greater than the density of the heat sink fins 122 of the second heat sink 124. Since the first heat sink 123 is in contact with a plurality of heat-generating components 111, by making the density of the heat sink fins 122 of the first heat sink 123 greater than the density of the heat sink fins 122 of the second heat sink 124, the area of the heat sink fins 122 of the first heat sink 123 may be greater than the area of the heat sink fins 122 of the second heat sink 124. Thus, the heat sink fins 122 of the first heat sink 123 can also effectively absorb the heat generated by the plurality of heat-generating components 111 during operation, which is beneficial to improving the heat dissipation effect. Or the density of the heat sink fins 122 of the first heat sink 123 may be smaller than the density of the heat sink fins 122 of the second heat sink 124, so that there is more heat dissipating space between adjacent heat sink fins 122 of the first heat sink 123, and the first heat sink 123 shares more air, thereby reducing air resistance, increasing ventilation, and improving dust deposition. This can also effectively dissipating heat generated during the working process of the plurality of heat-generating components 111.

In an optional implementation, the total surface area of the heat sink fins 122 of the first heat sink 123 is greater than the total surface area of the heat sink fins 122 of the second heat sink 124. This is beneficial for lowering the overall temperature of the plurality of heat-generating components 111, while lowering the maximum temperature of the plurality of heat-generating components 111.

Of course, the present application is not limited to the above. In another optional implementation, the total surface area of the heat sink fins 122 of the first heat sink 123 may be less than the total surface area of the heat sink fins 122 of the second heat sink 124. In this way, the amount of dust accumulation of the first heat sink 123 can be further reduced, and the heat generated by the plurality of heat-generating components 111 in the working process may be effectively dissipated.

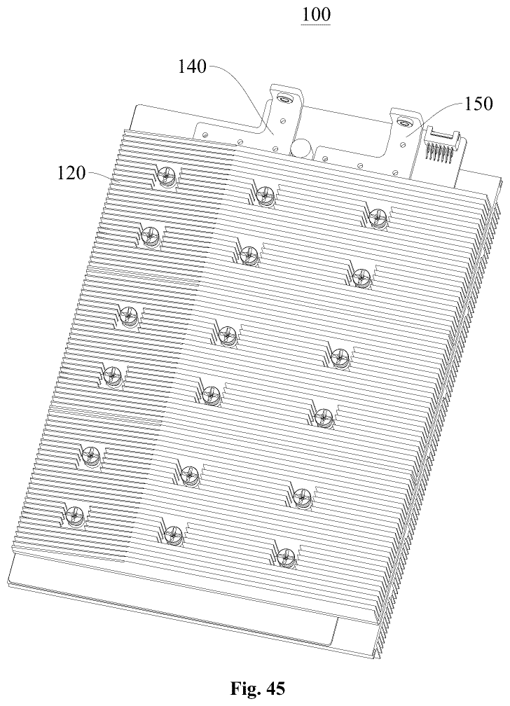

In one implementation, as shown in FIGS. 45-51, the number of heat sink fins 122 of the first heat sink 123 may be less than the number of heat sink fins 122 of the second heat sink 124. In this way, the total surface area of the heat sink fins 122 of the first heat sink 123 may be relatively small, thereby increasing the ventilation volume and reducing dust accumulation. This also can effectively dissipate the heat generated by the plurality of heat-generating components 111 in the working process.

In one implementation, with reference to FIGS. 45-51, along the second direction, an end of the second heat sink 124 exceeds a corresponding end of the first heat sink 123. For example, in the examples of FIGS. 45 to 51, along the second direction, the size of the second heat sink 124 is larger than the size of the first heat sink 123, and both ends of the second heat sink 124 exceed corresponding ends of the first heat sink. With such an arrangement, the number of heat sink fins 122 of the second heat sink 124 is relatively large, and the total surface area of its heat sink fins 122 is relatively large. The heat generated in the working process of the circuit board 110 may be effectively discharged through the heat sink fins 122 of the second heat sink 124. At the same time, the number of the first heat sink 123 may be relatively small, and the total surface area of its heat sink fins 122 is relatively small, which can further relieve the problem of serious dust accumulation on the first heat sink 123, increase the ventilation volume of the first heat sink 123, and further improve the heat dissipation effect.

In one implementation, the density of the heat-generating components 111 close to an air inlet of the heat-dissipating air duct may be greater than the density of the heat-generating components 111 close to the air outlet. Since the air entering from the air inlet is cold air and the air exiting from the air outlet is hot air, the heat generated by the heat-generating components 111 at the air inlet may be increased by increasing the density of the heat-generating components 111 at the air inlet, and the heat generated by the heat-generating components 111 at the air outlet may be reduced by reducing the density of the heat-generating components 111 at the air outlet, thereby further reducing the maximum temperature difference between the heat-generating components 111 close to the air outlet and the heat-generating components 111 close to the air inlet and improving the temperature uniformity of the heat-generating components 111.

In one implementation, as shown in FIG. 52, the plurality of the heat-generating components 111 close to the air outlet are divided into a plurality of groups of heat-generating components along the second direction, and the gap between two adjacent groups of heat-generating components is greater than the gap between two adjacent heat-generating components 111 in each group of heat-generating components.

For example, six columns of heat-generating components 111 are shown in the example of FIG. 52. For the convenience of description, the six columns of heat-generating components 111 sequentially arranged along the first direction are respectively referred to as the first heat-generating column, the second heat-generating column, . . . , the sixth heat-generating column. There are 21 heat-generating components 111 in the first to third heat-generating columns, and there are 19 heat-generating components 111 in the fourth to sixth heat-generating columns. The 21 heat-generating components 111 in the first to the third heat-generating columns are evenly spaced. The 19 heat-generating components 111 in the fourth to sixth heat-generating columns are divided into three groups of heat-generating components, and the number of heat-generating components 111 is the same in the groups of heat-generating components located at two ends in the second direction among the three groups of heat-generating components, and the number of heat-generating components 111 in the group of heat-generating components located at the middle in the second direction is less than the number of heat-generating components 111 in the groups of heat-generating components at two ends.

In this embodiment, there may be a larger heat dissipation gap between two adjacent groups of heat-generating components at the air outlet, which can reduce the temperature near the air outlet and further reduce the maximum temperature difference between the air inlet and the air outlet, thereby improving the temperature uniformity of the working assembly 100.

In one implementation, the heat-generating components 111 may be arranged in various forms, such as in chip arrays. From the first column close to the air inlet (such as the first heat-generating column mentioned above) to the last column close to the air outlet (such as the sixth heat-generating column mentioned above), the number of chips in each column is not completely equal. The number of chips in each column may be gradually decreased, for example, 21, 20, 19, 18, 17, 16; it may be partially decreased, for example, 21, 21, 21, 19, 19, 19; it may also be a jump in number, for example, 21, 21, 20, 19, 20, 21; or 21, 21, 20, 19, 18, 21; other numbers of chip arrays may also be set according to heat dissipation requirements, so that the total number of chips in the front half close to the air inlet is greater than the total number of chips in the back half close to the air outlet. The front half and the back half here may be divided in half in terms of the number of chip columns, or in half in terms of the size of the circuit board 110. As shown in FIG. 52, the total number of chips in the first three columns close to the air inlet is set to be greater than the total number of chips in the last three columns close to the air outlet.

Due to the change in the number of chips in each column, the arrangement of the chips in each row may also be combined in different forms, and the number of chips in each row may be different. For example, some rows of chips are arranged in a straight line with the center points of the chips, while the center points of some rows of chips do not form a straight line, such as in a stepped arrangement (for example, in line with the above “the number of chips in each column gradually decreases, for example, 21, 20, 19, 18, 17, 16”, the row direction presents a stepped arrangement). There are also different embodiments for the number of chips in each row. For example, in the second direction, the number of chips in the rows close to the two ends of the circuit board 110 is greater than the number of chips in the row close to the center of the circuit board 110. In short, the total chip distribution and/or quantity is divided, and the total number of chips in each part meets the preset distribution requirements.

Specifically, in the second direction, the circuit board 110 is divided into three parts from left to right based on the number of chips in the first heat-generating column, namely, the first part, the second part and the third part. The total number of chips in the first part or the third part close to the two ends of the circuit board 110 is greater than the number of chips in the second part in the middle. In another embodiment, if the circuit board 110 is divided into two parts from left to right in the second direction based on the number of chips in the first heating column, the number of chips in the first part is less than or equal to the number of chips in the second part.

With reference to FIG. 52, the above-mentioned specific division is based on the number of chips in the first heat-generating column in the second direction. In one embodiment, it is divided by way of average division. The circuit board 110 is divided into three parts from left to right. There are 21 chips in the first heat-generating column. The circuit board 110 is divided into three parts from left to right with every 7 chips in the first heat-generating column are divided into a part accordingly. Then, the total number of chips in the first part is 42, the total number of chips in the second part is 36, and the total number of chips in the third part is 42. The total number of chips in the first part (i.e., 42) or the third part (i.e., 42) close to the two ends of the circuit board 110 is greater than the number of chips in the middle second part (i.e., 36). If in the second direction, the circuit board 110 is divided into two parts from left to right based on the number of chips in the first heat-generating column, the circuit board 110 may be divided into two parts from left to right with the center axis of the 11th chip in the middle of the first heat-generating column as the dividing point, and then the number of chips in the first part (i.e., 57) is equal to the number of chips in the second part (i.e., 57). Those skilled in the art will understand that the way of division is not limited to the ways described above, and when the total number of chips in the first heat-generating column is an odd number or an even number, the way of division may be flexibly selected. Of course, the overall area formed by the edges of the chips disposed on the circuit board may be used as a reference for segmentation and division. The area may be evenly divided, or divided according to other proportions, so that the total number of chips in each part meets the preset distribution requirements.

In short, the arrangement of the chips may be set according to the heat dissipation conditions at various positions in the air duct. For example, the ambient temperature at the air inlet is low and the overall heat dissipating efficiency is high, more chips may be arranged. If the ambient temperature at the air outlet is high and the overall heat dissipating efficiency is low, fewer chips may be arranged, and the total number of chips close to the air outlet is less than the total number of chips close to the air inlet. At the same time, the temperatures at the upper and lower ends of the circuit board 110 in the direction perpendicular to the air direction are lower than the temperature at the center of the circuit board 110. In this case, more chips may be arranged at the two ends and fewer chips may be arranged at the center. The total number of chips at the two ends is greater than the total number of chips in the center. Alternatively, after being divided into two parts, the total number of chips in the lower half may be greater than the total number of chips in the upper half. This is a completely different design idea from conventionally changing the thermal resistance of the heat sink to achieve uniform temperature.

In one implementation, with reference to FIGS. 31 and 39A-42, a first connection base 140 and a second connection base 150 are provided at an end of the circuit board 110 in the second direction, and the first connection base 140 and the second connection base 150 are spaced apart in the first direction, wherein the second direction is perpendicular to the first direction. For example, the first connection base 140 and the second connection base 150 may be aluminum bases or copper bases. The thickness of the connection base when it is made of aluminum may be greater than when it is made of copper. Therefore, by disposing the first connection base 140 and the second connection base 150, compared with the way of disposing a plurality of connection plates in the prior art, the first connection base 140 and the second connection base 150 are simpler in structure and easier to process, which can effectively improve the assembly efficiency of the working assembly 100. Illustratively, through holes are provided on the first connection base 140 and the second connection base 150, and the through holes may be used for welding alignment. In addition, the through holes provided on the first connection base 140 and the second connection base 150 are also conducive to exhausting gas when welding the first connection base 140 and the second connection base 150.

Further, as shown in FIGS. 39A-42, the first connection base 140 include a first connection portion 141 and a first connection base body 142 connected to each other. The first connection portion 141 is connected to the circuit board 110, and the first connection base body 142 is connected to the power supply module 270. The second connection base 150 includes a second connection portion 151 and a second connection base body 152 connected to each other, the second connection portion 151 is connected to the circuit board 110, and the second connection base body 152 is connected to the power supply module 270. The first connection portion 141 is connected to a first surface of the circuit board 110, one end of the first connection base body 142 is connected to the first connection portion 141, and the other end of the first connection base body 142 extends away from the circuit board 110 along a third direction, wherein the third direction is perpendicular to the first surface. Similarly, the second connection portion 151 is connected to the first surface of the circuit board 110, one end of the second connection base body 152 is connected to the second connection portion 151, and the other end of the second connection base body 152 extends away from the circuit board 110 along the third direction.

For example, the first connection base body 142 and the second connection base body 152 both include a first connection segment, a second connection segment, and a third connection segment. One end of the first connection segment of the first connection base body 142 may be connected to the first connection portion 141, and one end of the first connection segment of the second connection base body 152 may be connected to the second connection portion 151. The other end of the first connection segment may be obliquely arranged in the direction away from the circuit board 110. One end of the second connection segment may be connected to the other end of the first connection segment, and the second connection segment may be disposed away from the first connection segment in a direction parallel to the first surface. One end of the third connection segment may be connected to the other end of the second connection segment, and the other end of the third connection segment may be disposed away from the circuit board 110 in a direction perpendicular to the first surface.

Therefore, by disposing the above-mentioned first connection portion 141, the first connection base body 142, the second connection portion 151 and the second connection base body 152, a firm connection between the first connection base 140 and the circuit board 110 can be achieved through the first connection portion 141, a firm connection between the second connection base 150 and the circuit board 110 may be achieved through the second connection portion 151, and the first connection base body 142 and the second connection base body 152 may extend outward to connect with a conductive connection member, thereby realizing power supply for the circuit board 110.

In one implementation, an avoidance slot 143 may be defined both between the first connection base body 142 and the first surface and between the second connection base body 152 and the first surface. For example, the avoidance slot 143 is co-defined by the first connection segment, the second connection segment and the first surface of the circuit board 110. In this way, the wiring harness may pass through the avoidance slot 143, thereby effectively playing the role of avoidance routing.

In one implementation, as shown in FIG. 40, the edge of the first connection portion 141 and the second connection portion 151 has a flanging 1411 extending in a direction away from the circuit board 110. With such a configuration, the flanging 1411 may effectively resist bending, so as to ensure the connection between the first connection portion 141 and the second connection portion 151 and the circuit board 110 to be more secure, preventing the edge of the first connection portion 141 and the second connection portion 151 from warping, and improving reliability.

In one implementation, with reference to FIGS. 39A, 42 and 43, a plurality of heat-generating components 111 are disposed on the first surface of the circuit board 110, a sealing member 160 is disposed between the first heat sink 123 and the circuit board 110, and the sealing member 160 is disposed close to the air inlet. For example, the sealing member 160 may be a rubber member. Therefore, by disposing the above-mentioned sealing member 160, the sealing performance between the first heat sink 123 and the circuit board 110 at the air inlet can be improved to prevent moisture from entering through the gap between the first heat sink 123 and the circuit board 110, thereby protecting the heat-generating components 111 close to the air inlet and meanwhile preventing air leakage.

In one implementation, with reference to FIGS. 39A, 42 and 43, the sealing member 160 includes a first sealing portion 161 and a second sealing portion 162. The first sealing portion 161 abuts against the edges of the circuit board 110 and the first heat sink 123 close to the air inlet, and the second sealing portion 162 is disposed on a side of the first sealing portion 161 away from the air inlet, and the second sealing portion 162 is located in a gap between the first heat sink 123 and the circuit board 110. Illustratively, the second sealing portion 162 divides the first sealing portion 161 into two parts, one of which contacts at least an edge of the heat sink body 121 of the first heat sink 123, and the other of which contacts at least an edge of the circuit board 110. There is an inlet between the edge of the heat sink body 121 of the first heat sink 123 close to the air inlet and the edge of the circuit board 110 close to the air inlet, and the second sealing portion 162 extends into the gap between the first heat sink 123 and the circuit board 110 through the inlet.

Therefore, by arranging the first sealing portion 161 and the second sealing portion 162 described above, the first sealing portion 161 has a better shielding effect, preventing moisture at the air inlet from directly contacting the heat sink body 121 of the first heat sink 123 or the circuit board 110, and the second sealing portion 162 has an effective sealing effect, further preventing moisture from entering the gap between the first heat sink 123 and the circuit board 110, thereby further improving the sealing of the first heat sink 123 and the circuit board 110 at the air inlet.

In one implementation, in conjunction with FIGS. 45-51, the working assembly 100 may not be provided with the sealing member 160, thereby ensuring the heat dissipation performance of the entire working assembly 100.

In one implementation, as shown in FIGS. 39A and 44, the circuit board 110 and the heat sink 120 may be connected via a connection member. For example, the connection member may be a screw, an elastic connection member, or the like.

In one implementation, as shown in FIGS. 39A and 44, the circuit board 110 and the heat sink 120 are connected by a spring screw 170, and the spring screw 170 includes a screw 172 and a spring 171 sleeved on the screw 172, and the end of the spring 171 close to the circuit board 110 extends in a direction away from the circuit board 110. For example, in the examples of FIGS. 39A and 44, the tail of the spring 171 is folded in the direction away from the circuit board 110. Therefore, although the spring 171 has a sharp end, the above-mentioned arrangement can prevent the end of the spring 171 from scraping aluminum chipping due to the contact between the end of the spring 171 and the surface of the circuit board 110, thereby avoiding damage to the circuit board 110 and improving the integrity and reliability of the circuit board 110.

An electronic device 200 according to an embodiment of the second aspect of the present application, such as a computing device, as shown in FIGS. 1-9A, includes the working assembly 100 according to any one of the implementations of the first aspect of the present application.

By adopting the working assembly 100 described above, the electronic device 200 according to the embodiments of the present application, such as a computing device, can reduce the maximum temperature difference between the heat-generating components 111 close to the air outlet and the heat-generating components 111 close to the air inlet, thereby improving the temperature uniformity of the heat-generating components 111.

In one implementation, with reference to FIGS. 1-9A, the electronic device 200 includes a housing 210 and a fan assembly 220. A heat-dissipating air duct having an air inlet and an air outlet is defined in the housing 210, and at least one working assembly 100 is disposed in the heat-dissipating air duct. The working assembly 100 includes a circuit board 110 and a plurality of heat sinks 120. The plurality of heat sinks 120 are disposed on at least one side of the circuit board 110. For example, the heat sinks 120 may be disposed on both sides of the circuit board 110. The surface of the circuit board 110 is parallel to a first direction, which extends from the air inlet to the air outlet. The fan assembly 220 is disposed on a side of the housing 210 close to the air inlet.

Illustratively, three working assemblies 100 are shown in FIG. 9A, and the three working assemblies 100 are arranged at intervals along a direction perpendicular to the surface of the circuit board 110. The heat sinks 120 may each include a heat sink body 121 and a plurality of heat sink fins 122. The plurality of heat sink fins 122 are disposed on a side of the heat sink body 121 at intervals along a second direction (for example, the vertical direction in FIG. 9A), wherein the second direction is perpendicular to the first direction and parallel to the surface of the circuit board 110.

The heat sink body 121 of the first heat sink 123 may contact the heat-generating components 111 on the first surface, and the heat sink body 121 of the second heat sink 124 may contact the second surface of the circuit board 110. The heat generated during the operation of the heat-generating components 111 may be conducted to the first heat sink 123 and the second heat sink 124. A heat dissipation channel extending along the first direction may be defined between two adjacent heat sink fins 122 and the heat sink body 121. When the fan assembly 220 is working, cold air enters from the air inlet, flows along the heat dissipation channels of the first heat sink 123 and the second heat sink 124, and exchanges heat with the first heat sink 123 and the second heat sink 124. The hot air after heat exchange flows out from the air outlet, thereby achieving heat dissipation of the working assembly 100.

By disposing the fan assembly 220 on the side of the housing 210 close to the air inlet so that the fan assembly 220 and the air outlet are located on opposite sides of the housing 210, when part of the working assemblies 100 is damaged, only the damaged working assembly 100 needs to be removed and taken out from the air outlet, and then the working assembly 100 with intact function is placed into the housing 210 through the air outlet and installed, without removing the fan assembly 220. This enables more convenient installation and disassembly of the working assembly 100 and can effectively improve the efficiency of servicing and replacement of the working assembly 100.

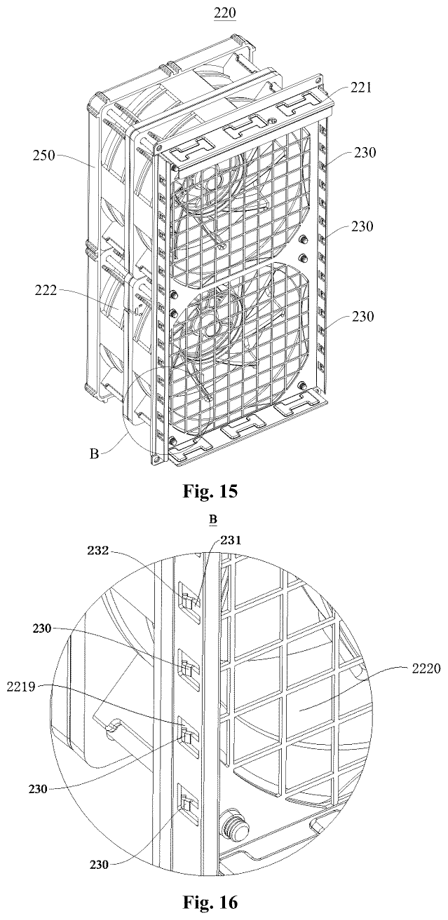

In one implementation, with reference to FIGS. 9A-15, the fan assembly 220 includes a mounting member 221 and a plurality of fan modules 222. The mounting member 221 is connected to the housing 210, and the plurality of fan modules 222 are connected to a side of the mounting member 221 facing away from the housing 210. For example, in the examples of FIGS. 15, 17 and 18, the mounting member 221 is greater than the fan module 222 in outline size. A plurality of first ventilation holes 2220 are formed on the portion of the mounting member 221 facing away from the fan module 222. When the fan module 222 is of the blowing type and the fan module 222 is operating, external air enters the heat-dissipating air duct through the plurality of first ventilation holes 2220 under the action of the fan module 222, exchanges heat with the first heat sink 123 and the second heat sink 124, and then flows out from the air outlet. When the fan module 222 is of suction type and the fan module 222 is operating, external air enters the heat-dissipating air duct through a plurality of second ventilation holes 2137 under the action of the fan module 222, exchanges heat with the first heat 123 and the second heat 124, and then flows out from the plurality of first ventilation holes 2220.

Therefore, by disposing the mounting member 221 and the plurality of fan modules 222 described above, the mounting member 221 can firmly fix the fan module 222 on the housing 210, thereby improving the structural stability and reliability of the entire electronic device 200. The plurality of fan modules 222 can increase the ventilation volume of the heat-dissipating air duct, reduce air resistance, and inhibit the deposition of dust on the heat sink 120, thereby effectively improving the heat dissipation effect of the working assembly 100.

In one implementation, the plurality of fan modules are divided into a plurality of fan groups arranged vertically. Each fan group includes two fan modules. The two fan modules are arranged opposite to each other in a direction from the air inlet to the air outlet.

In one implementation, through holes are formed on four corners of each fan module, threaded holes are formed on the mounting member, and threaded fasteners pass through the through holes of the two fan modules and are threadedly connected to corresponding threaded holes, respectively.

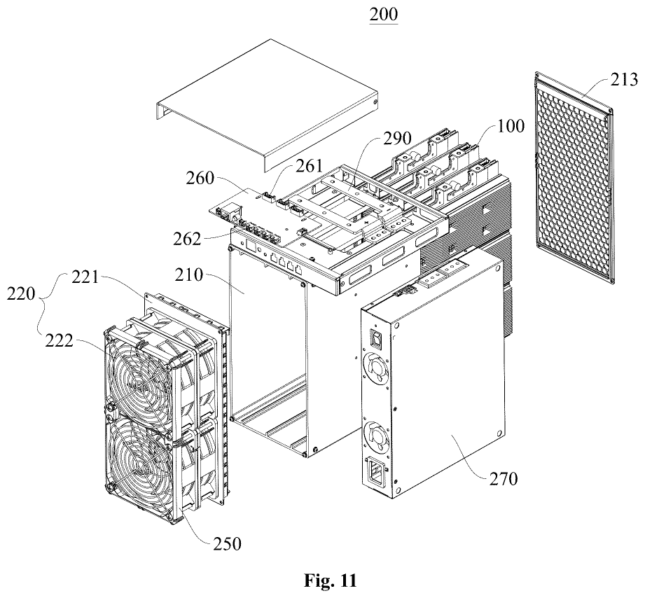

In one implementation, as shown in FIGS. 11 and 14-16, at least one first elastic component is provided on the mounting member 221, and the first elastic component is pressed tightly between the mounting member 221 and the corresponding side wall of the housing 210 to achieve a secure installation between the mounting member 221 and the housing 210 and prevent the mounting member 221 from falling off the housing 210.

In one implementation, as shown in FIGS. 11 and 14-16, the mounting member 221 includes a mounting body 2213, a mounting top plate 2215 and a mounting bottom plate 2216 that are oppositely disposed, two mounting side plates 2214, and a first bent portion 2217. A fan module 222 is connected to the mounting body 2213, and a plurality of first ventilation holes 2220 are formed on the mounting body 2213. The mounting top plate 2215 and the mounting bottom plate 2216 are disposed on a side of the mounting body 2213 facing away from the fan module. The mounting top plate 2215 is connected to the upper part of the mounting body 2213, and the mounting bottom plate 2216 is connected to the lower part of the mounting body 2213. The two mounting side plates 2214 are disposed on a side of the mounting body 2213 facing away from the fan module 222. Furthermore, the two mounting side plates 2214 are respectively connected to two sides of the mounting body 2213. The first elastic component is disposed on at least one of the two mounting side plates 2214. The first bent portion 2217 is connected to an end of the mounting top plate 2215 facing away from the mounting body 2213. In one implementation, the working assembly abuts against the first bent portion 2217, the mounting top plate 2215, the mounting bottom plate 2216 and each mounting side plate 2214 is perpendicular to the mounting body 2213, and the first bent portion 2217 is parallel to the mounting body 2213. In one implementation, a plurality of reinforcing ribs 2218 arranged at intervals are provided on the mounting top plate 2215 and/or the mounting bottom plate 2216.

Illustratively, in combination with FIGS. 11 and 13-16, the mounting top plate 2215, the mounting bottom plate 2216 and each mounting side plate 2214 may all be perpendicular to the mounting body 2213. The mounting top plate 2215 is connected between the mounting body 2213 and the first bent portion 2217, and the first bent portion 2217 is parallel to the mounting body 2213. After installation, the working assembly 100 may abut against the first bent portion 2217, so that, on one hand, there is a certain gap between the mounting member 221 and the working assembly 100 in the first direction. When the external air enters the heat-dissipating air duct from the fan module 222, it may flow evenly in the gap between the mounting member 221 and the working assembly 100, and then flow through the first heat sink 123 and the second heat sink 124 to improve the heat dissipation effect. On the other hand, the first bent portion 2217 may play an effective role in blocking the air, so that the air entering from the air inlet may flow into the working assembly 100 as much as possible, thereby avoiding the waste of air volume.

A plurality of I-shaped reinforcement ribs 2218 may be provided on the mounting top plate 2215 and the mounting bottom plate 2216 to prevent the mounting top plate 2215 and the mounting bottom plate 2216 from bending and warping, thereby improving the structural strength of the entire mounting component 221 and ensuring the structural stability of the electronic device 200.

In one implementation, the at least one first elastic component includes a plurality of first elastic clips 230 spaced apart from each other vertically, and free ends of the first elastic clips 230 are pressed tightly between the mounting side plate 2214 and the corresponding side wall of the housing.

Illustratively, a plurality of via holes 2219 disposed at intervals vertically may be formed on the mounting side plate 2214, and a plurality of first elastic clips 230 are disposed in the plurality of via holes 2219 in a one-to-one correspondence. One end of each first elastic clip 230 is connected to the edge of the corresponding via hole 2219, and the other end (i.e., the free end) of each first elastic clip 230 extends in a direction opposite to the first direction. When the mounting member 221 is mounted on the housing 210, the side wall of the housing 210 presses the other end of each first elastic clip 230, so that each first elastic clip 230 generates elastic deformation. When the mounting member 221 is removed from the housing 210, the first elastic clip 230 returns to its original state. The first elastic clips 230 are all made of metal.

In one example, as shown in FIG. 16, each first elastic clip 230 may include a connection portion 231 and an abutment portion 232. One end of the connection portion 231 is connected to the first edge of the corresponding via hole 2219. One end of the abutment portion 232 is connected to the other end of the connection portion 231, and the other end of the abutment portion 232 is spaced apart from the opposite side edge of the first edge. The abutment portion 232 abuts against the corresponding side wall of the housing 210.

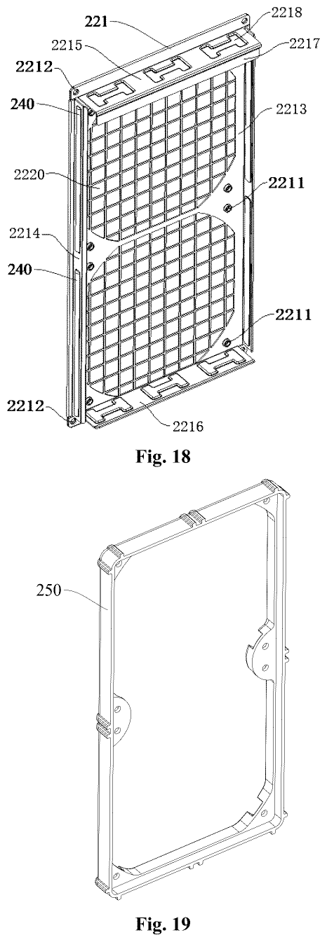

Therefore, the mounting member 221 and the housing 210 may be electrically connected via the plurality of first elastic clips 230, thereby playing an effective shielding and grounding role and improving the safety of the electronic device 200. In another implementation, with reference to FIG. 18 in combination with FIG. 11, the at least one first elastic component described above includes a first conductive foam 240 extending in the vertical direction, and the mounting member 221 is in elastic contact with the corresponding side wall of the housing 210 through the first conductive foam 240. For example, the first conductive foam 240 may be adhered to the two mounting side plates 2214 by an adhesive. Optionally, the first conductive foam 240 may be a conductive foam, but is not limited thereto. In this way, the mounting member 221 and the housing 210 may be electrically connected via the first conductive foam 240, thereby also playing an effective shielding and grounding role and improving the safety of the electronic device 200.

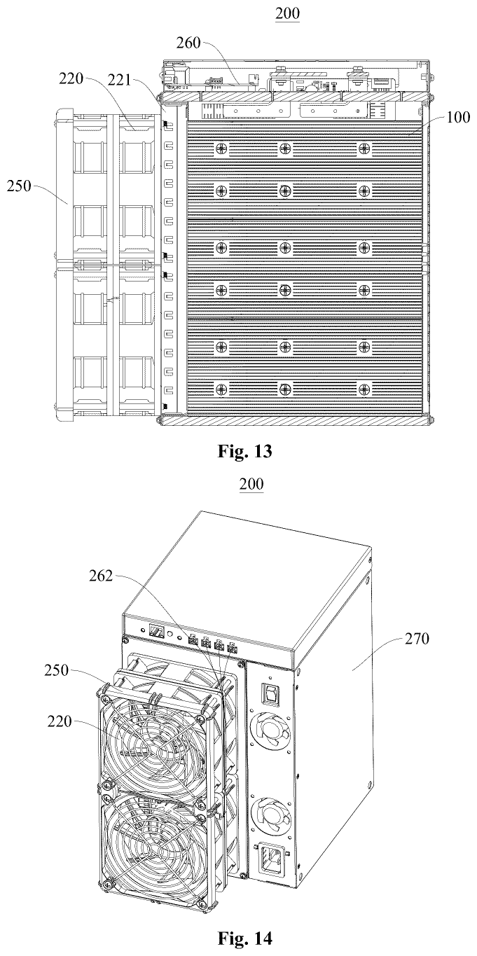

In one implementation, as shown in FIG. 13, the fan module 222 and the working assembly 100 are spaced apart in the first direction. For example, in the example of FIG. 13, there is a certain gap between the mounting member 221 and the working assembly 100 in the first direction. When the external air enters the heat-dissipating air duct from the fan module 222, it can flow evenly in the gap between the mounting member 221 and the working assembly 100, and then flow through the first heat sink 123 and the second heat sink 124. Thus, the gap between the fan module 222 and the working assembly 100 may allow air to flow into the heat sink 120 more evenly, thereby improving the heat dissipation effect.

In one implementation, with reference to FIGS. 14-19, a flexible protective cover 250 is disposed on a side of the fan module 222 away from the mounting plate, and the flexible protective cover 250 is sleeved on an outer periphery of the fan module 222. Therefore, the flexible protective cover 250 configured in this way can effectively protect the edges and corners of the fan module 222, thus preventing the fan module 222 from being worn, and it may prevent the edges and corners of the fan module 222 from scratching workers, thereby improving safety. Optionally, the material of the flexible protective cover 250 may be soft rubber material, but is not limited thereto.

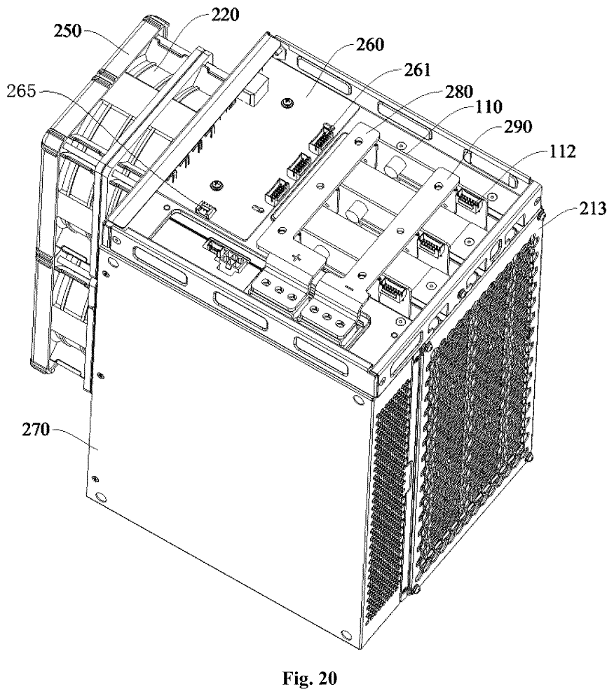

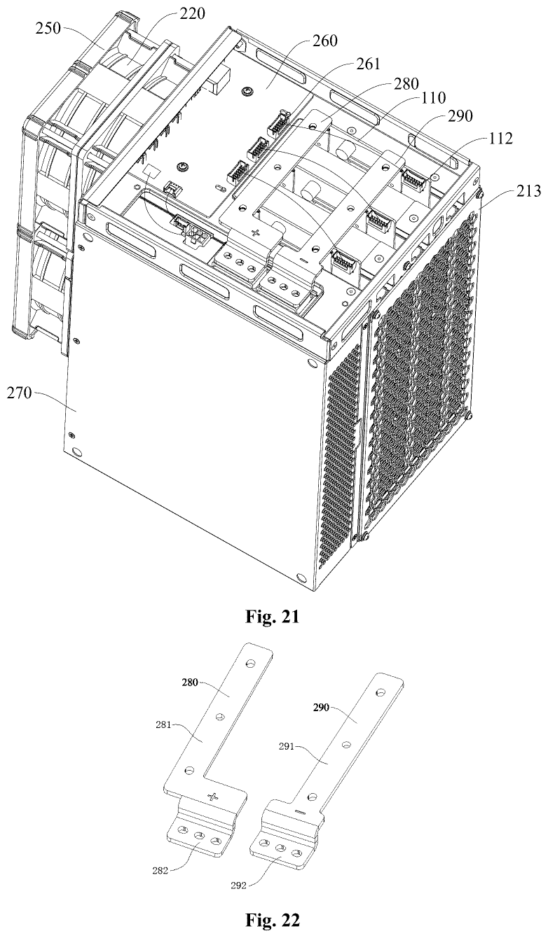

In one implementation, as shown in FIGS. 20 and 21, a control board 260 is provided on the top of the housing 210, and a plurality of fan interfaces 262 are provided on the control board 260. The plurality of fan interfaces 262 are connected to the plurality of fan modules 222 in a one-to-one correspondence, wherein the plurality of fan interfaces 262 are all disposed close to the air inlet. In this way, the plurality of fan interfaces 262 are disposed close to the plurality of fan modules 222, which facilitates the wiring between the plurality of fan interfaces 262 and the plurality of fan modules 222.

Illustratively, a first signal socket 112 is disposed on the circuit board 110, and a second signal socket 261 is disposed on the control board 260, and the second signal socket 261 is connected to the first signal socket 112. For example, in the examples of FIGS. 20 and 21, there are three second signal sockets 261, and the three second signal sockets 261 may be connected one-to-one with the circuit boards 110 of the three working assemblies 100 through three first cables, so that the control board 260 can control the operation of the circuit board 110.

Illustratively, the second signal sockets 261 are close to the first signal sockets 112. Illustratively, when there are three second signal sockets 261, there are three first signal sockets 112, wherein the three second signal sockets 261 are disposed on a side of the control board 260 close to the first signal sockets 112. Such a configuration may facilitate the connection between the second signal sockets 261 and the first signal sockets 112 using the shortest connection line.

Illustratively, there are four fan interfaces 262 and four fan modules 222, and the four fan interfaces 262 may be connected to the four fan modules 222 in a one-to-one correspondence through four second cables, so that the control board 260 can control the operation of the working modules.

Illustratively, the four fan modules 222 are divided into two groups, and two fan modules 222 in each group are connected together by screws and fixed to the mounting member 221 by screws. Each fan module 222 is provided with through holes at four corners for screws to pass through, and correspondingly, the mounting member 221 is provided with threaded holes 2211 for screws to pass through to achieve assembly between the fan module 222 and the mounting member. Illustratively, the mounting member 221 is further provided with a plurality of fixing holes 2212 for fixing the mounting member 221 to the housing 210. For example, four fixing holes 2212 are provided at the four corners of the mounting member 221, and correspondingly, fixing holes are provided on the housing 210.

Therefore, through the above configuration, on the one hand, signal connection between the control board 260 and the fan module 222 and between the control board 260 and the circuit board 110 can be achieved; on the other hand, by disposing all of the plurality of fan interfaces 262 close to the air inlet, the plurality of fan interfaces 262 can be centrally disposed on the control board 260, and the structure is more compact, occupying less space, and facilitating the spatial layout of other modules on the control board 260.

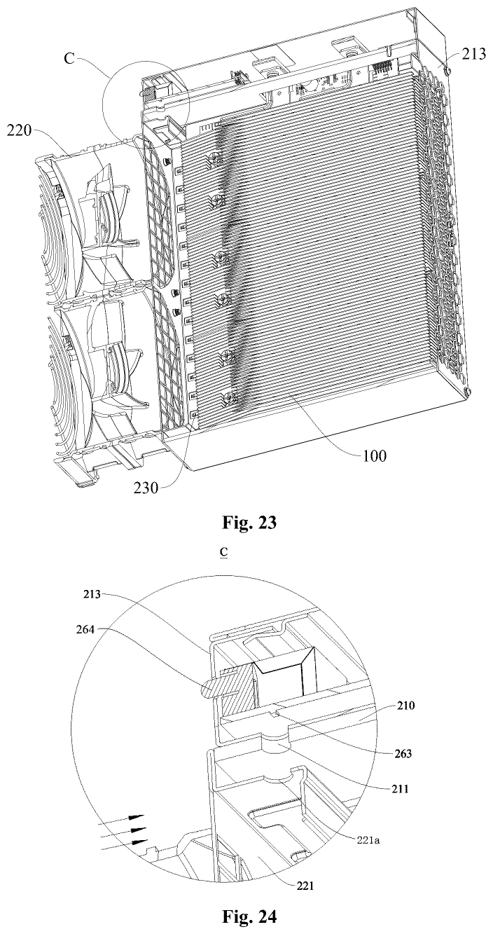

In one implementation, with reference to FIGS. 23-25B, a top housing 212 is disposed on the top of the housing 210, and a control board 260 is disposed in the top housing 212. The control board 260 is provided with a temperature sensor 263 for sensing the temperature at the air inlet. In this way, a user may know the temperature at the air inlet in real time, avoid the temperature of the air entering from the air inlet being too high, and endow the working assembly 100 with a better heat dissipation effect, thereby ensuring the normal operation of the working assembly 100 and effectively extending the service life of the entire electronic device 200.

In one implementation, as shown in FIGS. 23 and 24, the temperature sensor 263 is disposed at the bottom of the control board 260, and the temperature sensor 263 is located within the top housing 212. The top surface of the housing 210 is formed with a ventilation hole 211 communicated with the heat-dissipating air duct, and the ventilation hole 211 corresponds to the temperature sensor 263 in position. For example, in the examples of FIGS. 23 and 24, a third ventilation hole 221a penetrating in the thickness direction is formed on the top of the mounting member 221, and the third ventilation hole 221a, the ventilation hole 211 and the temperature sensor 263 correspond to each other in the vertical direction.

Therefore, the temperature sensor 263 in the above implementations can sense the temperature at the air inlet through the ventilation hole 211. Moreover, the temperature sensor 263 may be hidden in the top housing 212 to prevent the temperature sensor 263 from direct contact with the external environment, so that the top housing 212 may effectively protect the temperature sensor 263 and prevent the temperature sensor 263 from being damaged, and may make the appearance of the electronic device 200 more neat and beautiful.

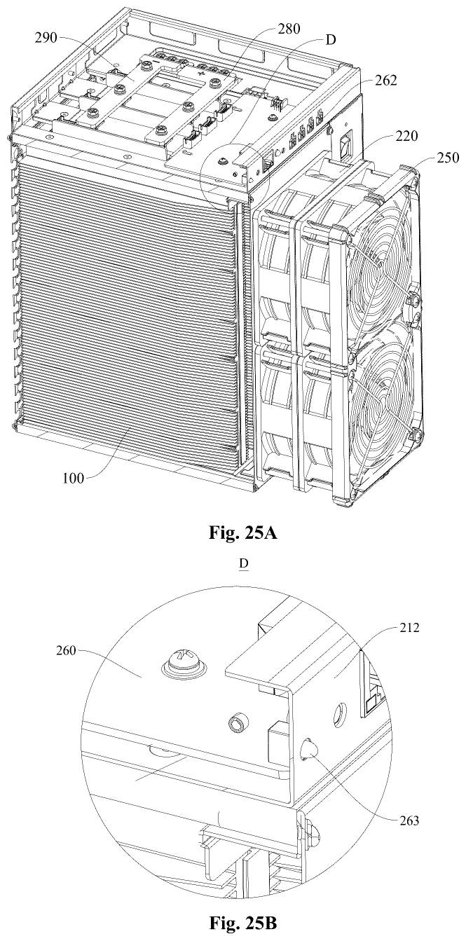

In another implementation, with reference to FIGS. 25A and 25B, the temperature sensor 263 is disposed on the top of the control board 260, and the temperature sensor 263 protrudes from a side surface of the top housing 212 close to the fan assembly 220. For example, in the examples of FIGS. 25A and 25B, a passage hole may be formed on the side of the top housing 212 close to the air inlet, the temperature sensor 263 may be set on the side of the control board 260 close to the air inlet, and the temperature sensor 263 protrudes out of the top housing 212 from the passage hole. With such configuration, the temperature sensor 263 can directly protrude out of the top housing 212 to sense the temperature at the air inlet, and no holes need to be opened on the housing 210 and the mounting member 221, thereby making the structure of the housing 210 simpler and easier to process.

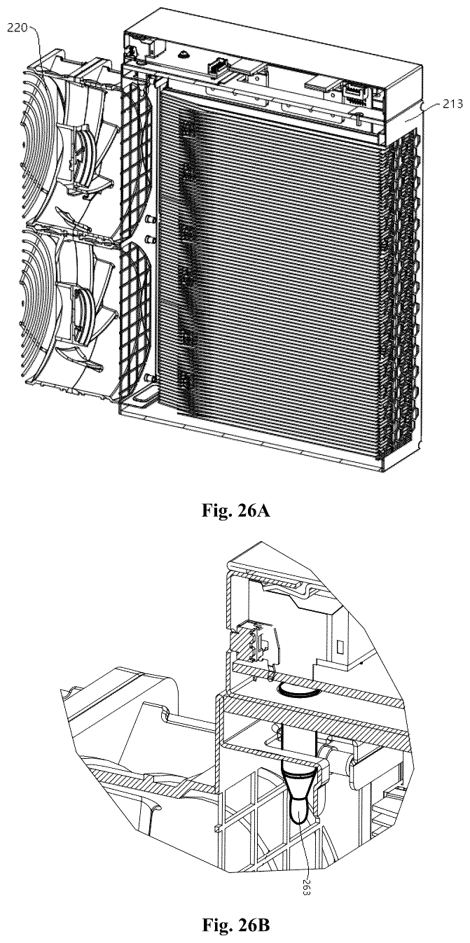

Of course, the present application is not limited thereto. In another implementation, as shown in FIGS. 26A and 26B, the free end of the temperature sensor 263 may pass through the top of the housing 210 and protrude into the housing 210 and be opposite to the fan assembly 220. In this way, the free end of the temperature sensor 263 can protrude into an air inlet cavity of the housing 210 to detect the temperature of the air input by the fan assembly 220 and can sense the temperature of the air inlet more accurately.

In the process of implementing the present invention, the inventors found that the indicator light of the electronic device 200 is usually disposed in the middle of the control board of the electronic device 200. When a plurality of fans are connected in series (for example, 4 fans) and installed on a front face of the electronic device 200, due to the viewing angle, the fan will block the indicator light, affecting the observation of the operation and maintenance personnel, especially when the electronic device 200 needs to be placed on a rack, sometimes at a higher position, in which case the fan will more easily block the indicator light.

Based on this, in one implementation, as shown in FIGS. 23 and 24, the electronic device 200 may further include an indicator light 264 to indicate the working status of the electronic device 200. The indicator light 264 is disposed on a side of the control board close to the air inlet, and is located at an end of the control board near the side of the air inlet.

Since the indicator light 264 is disposed at the end of the side of the control board, the indicator light may be observed from one side of the electronic device 10, thus avoiding the situation where the fan blocks the indicator light.

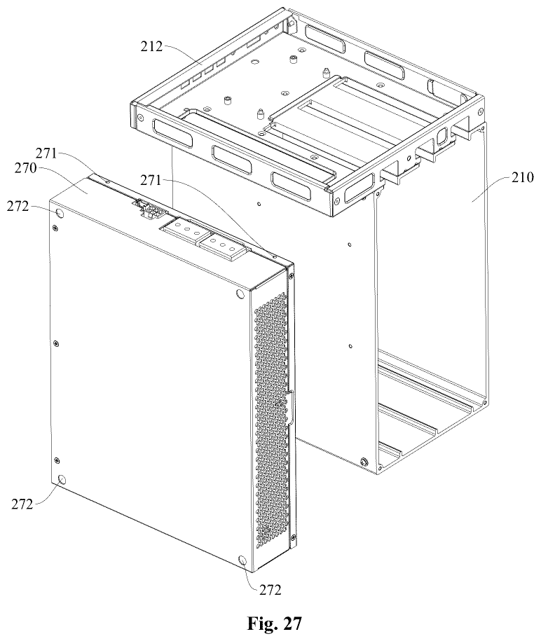

In one implementation, as shown in FIGS. 27-29B, the electronic device 200 further includes: a power supply module 270 disposed on one side of the housing 210 in a third direction and configured to supply power to the circuit board 110 and the fan assembly 220, wherein the third direction is perpendicular to the surface of the circuit board 110.

Illustratively, the housing 210 is generally a cuboid structure, and the housing 210 may include a top surface, a bottom surface, and four side surfaces, and the four side surfaces are respectively connected between the top surface and the bottom surface. The top surface and the bottom surface are opposite to each other in the second direction. The top of the power supply module 270 is connected to the top housing 212, and the side surfaces of the power supply module 270 is connected to side surfaces of the housing 210.

Along the third direction, the top housing 212 includes two first side surfaces that are disposed opposite to each other and two second side surfaces that are disposed opposite to each other, wherein one of the two second side surfaces is coplanar with (i.e., flush with) the corresponding side surface of the housing 210, the other of the two second side surfaces is coplanar with the corresponding side surface of the power supply module 270, the respective first side surfaces are coplanar with the corresponding side surfaces of the housing 210 and the power supply module 270 at the same time, and the bottom surface of the power supply module 270 is coplanar with the bottom surface of the housing 210.

Specifically, for example, the two first side surfaces of the top housing 212 may be a front side surface and a rear side surface, respectively, and the two second side surfaces of the top housing 212 may be a left side surface and a right side surface, respectively. The front side surface of the top housing 212 may be flush with the front side surface of the housing 210 and the front side surface of the power supply module 270, the rear side surface of the top housing 212 may be flush with the rear side surface of the housing 210 and the rear side surface of the power supply module 270, the left side surface of the top housing 212 may be flush with the left side surface of the housing 210, the right side surface of the top housing 212 may be flush with the right side surface of the power supply module 270, and the bottom surface of the power supply module 270 is flush with the bottom surface of the housing 210.

It should be supplemented that in the above solution, “coplanar” refers to a situation in comparison to a significant height difference, for example, a height difference between two surfaces of more than 2 cm. The coplanar here may be understood as follows: the two surfaces are in the same plane or the two surfaces have a certain deviation distance, but the visual effect is almost flush. Those skilled in the art will understand that the housing 210 and the power supply module 270, the power supply module 270 and the top housing 212, and the housing 210 and the top housing 212 in the above solution may not be strictly flush due to screws, protective layer structures, reinforcement structures or paint, but as long as faces of corresponding two structures are substantially flush, they all fall within the scope of protection defined by “coplanar” in the present application. In other words, the coplanar mentioned in the present application is to ensure that the outer contours of the electronic device 200 composed of the housing 210, the power supply module 270 and the top housing 212 are substantially flush to the extent of tending to occupy the same plane in geometric mathematics, so as to play a role in optimizing the overall shape layout of the electronic device 200 to facilitate disassembly, installation and use.

It should be noted that the above-mentioned “front” refers to the direction close to the air inlet of the heat-dissipating air duct, and the opposite direction is defined as “rear”, that is, the direction close to the air outlet of the heat-dissipating air duct. “Left” refers to the direction extending along the power supply module 270 toward the housing 210; “right” refers to the direction extending along the housing 210 toward the power supply module 270. Correspondingly, the “front side surface” refers to the side surface close to the air inlet of the heat-dissipating air duct, and the “rear side surface” refers to the side surface close to the air outlet of the heat-dissipating air duct. The “left side surface” refers to the side surface in the direction from the power supply module 270 toward the housing 210, and the “right side surface” refers to the side surface in the direction from the housing 210 toward the power supply module 270.

Therefore, through the above-mentioned power supply module 270, while supplying power to the circuit board 110 and the fan assembly 220, the power supply module 270 may effectively utilize the space between the top housing 212 and the housing 210, thereby making the structure of the entire electronic device 200 more compact and the appearance more neat and beautiful.

In one implementation, as shown in FIGS. 27-30B, at least one positioning hole 271 is formed on one of the power supply module 270 and the top housing 212, and at least one positioning protrusion is provided on the other of the power supply module 270 and the top housing 212, and the positioning protrusion is fitted into the corresponding positioning hole 271. At least one second through hole 272 is formed on one of the power supply module 270 and the housing 210, and at least one threaded hole corresponding to the second through hole 272 is formed on the other of the power supply module 270 and the housing 210. The threaded fastener 273 is suitable for passing through the second through hole 272 and being threadedly connected with the threaded hole.

For example, in the examples of FIGS. 27-30B, two positioning holes 271 are formed on the top of the power supply module 270, and the two positioning holes 271 are disposed at intervals along the first direction. Correspondingly, two positioning protrusions disposed at intervals in the first direction may be disposed on the bottom surface of the top housing 212, and the two positioning protrusions correspond one-to-one to the two positioning holes 271. Four second through holes 272 are formed on a side surface of the power supply module 270, and the four second through holes 272 are respectively located at the four corners of the power supply module 270. Four threaded holes corresponding one-to-one to the four second through holes 272 are formed on the second side surface of the housing 210. During installation, the two positioning protrusions may be respectively fitted into the corresponding positioning holes 271 to achieve positioning of the power supply module 270. Then, four threaded fasteners 273 are respectively passed through the corresponding second through holes 272 and threadedly connected with the corresponding threaded holes to fix the power supply module 270.

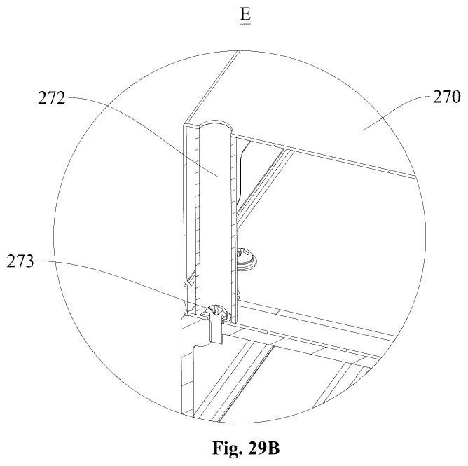

In one example, as shown in FIGS. 29A and 29B, all the threaded fastener 273 may be short screws. In this case, the threaded fasteners 273 may pass through one of the side walls of the power supply module 270 and be threadedly connected to the threaded holes on the housing 210 respectively. At this time, one of the side walls of the power supply module 270 is pressed tightly between the head of the threaded fastener 273 and the housing 210.

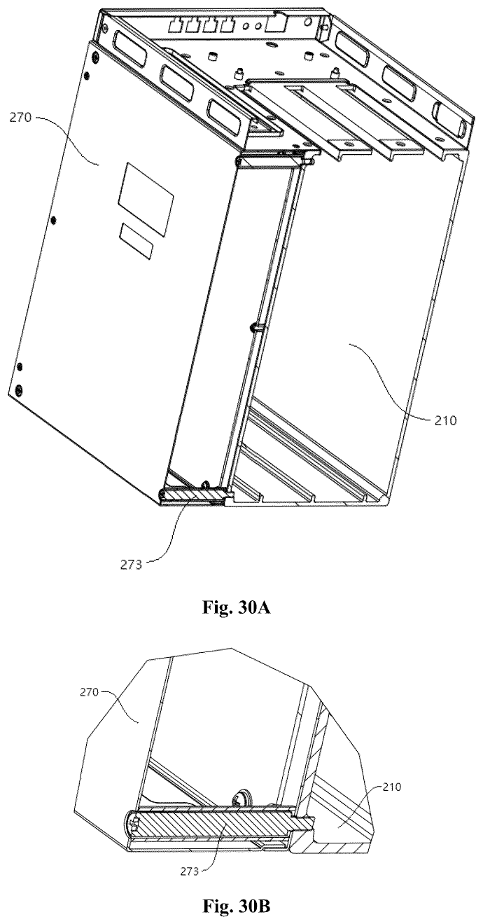

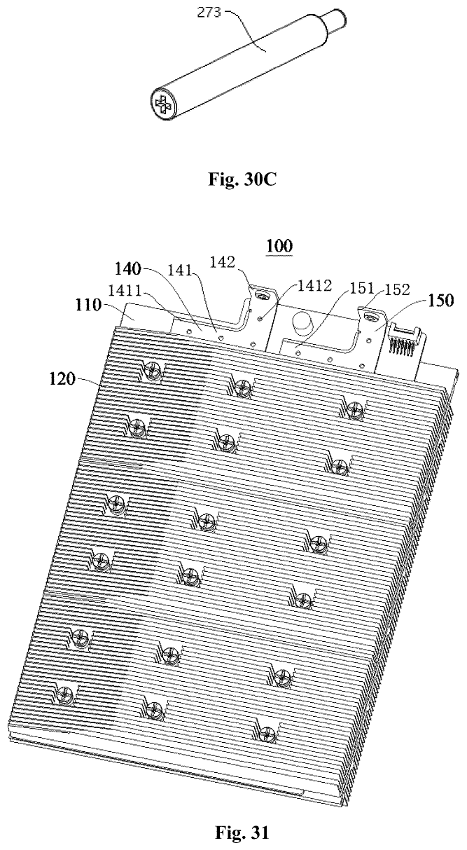

In another example, as shown in FIGS. 30A-30C, all the threaded fastener 273 may be long screws. In this case, the threaded fasteners 273 may pass through two side walls of the power supply module 270 and be threadedly connected to the threaded holes on the housing 210 respectively. At this time, the entire power supply module 270 is pressed tightly between the head of the threaded fastener 273 and the housing 210. This fixing method has better visibility and facilitates the installation and removal of threaded fasteners 273 such as screws.

Of course, it is also possible to have some threaded fasteners 273 as short screws and others as long screws, which is not limited in the present application.

Therefore, the power supply module 270 may be positioned relative to the housing 210 in advance by the cooperation of the positioning protrusion and the positioning hole 271, preventing the power supply module 270 from shifting during the process of being assembled with the housing 210, thereby improving installation efficiency. Moreover, the power supply module 270 and the housing 210 may be directly threadedly connected via the threaded fastener 273, which eliminates the need for a bracket between the power supply module 270 and the housing 210 and makes the structure simpler.

In one implementation, with reference to FIGS. 20-22, the electronic device 200 further includes a first conductive connection member 280 and a second conductive connection member 290. Specifically, a portion of the first conductive connection member 280 is electrically connected to the power supply module 270, and another portion of the first conductive connection member 280 is electrically connected to the first connection base 140 of the working assembly 100. A portion of the second conductive connection member 290 is electrically connected to the power supply module 270, and another portion of the first conductive connection member 290 is electrically connected to the second connection base 150 of the working assembly 100.

For example, in the examples of FIGS. 20-22, the bottom surface of the above-mentioned other part of the first conductive connection member 280 may contact the top surface of the third connection segments of the three first connection bases 140, and the first fastener is suitable for passing through the first conductive connection member 280 to connect with the third connection segment of the corresponding first connection base 140. The bottom surface of the above-mentioned other part of the second conductive connection member 290 may contact the top surfaces of the third connection segments of the three second connection bases 150, and the second fastener is suitable for passing through the second conductive connection member 290 to connect with the third connection segment of the corresponding second connection base 150. The above-mentioned other portion of the first conductive connection member 280 may be parallel to the above-mentioned other portion of the second conductive connection member 290, and both extend along the third direction. The first conductive connection member 280 may be a positive electrode conductive bar, and the second conductive connection member 290 may be a negative electrode conductive bar.

Therefore, by disposing the first conductive connection member 280 and the second conductive connection member 290 described above, electrical connection between the power supply module 270 and the circuit board 110 may be achieved, so that current may be input from the power supply module 270 into the circuit board 110 to achieve power supply for the circuit board 110. Moreover, the first conductive connection member 280 and the second conductive connection member 290 have simple structures and are easy to arrange.

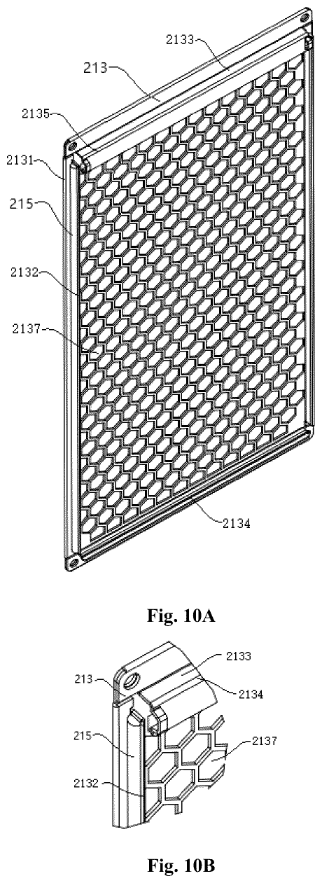

In one implementation, as shown in FIGS. 9A-10B, a ventilation panel 213 is provided on the side of the housing 210 facing away from the fan assembly 220, at least one second elastic component is provided at the edge of the ventilation panel 213, and the second elastic component is pressed tightly between the ventilation panel 213 and the corresponding side wall of the housing 210. Therefore, by providing the above-mentioned second elastic component, the second elastic component may be squeezed into the housing 210, so that the connection between the ventilation panel 213 and the housing 210 is more stable, and the ventilation panel 213 is prevented from falling off from the housing 210.

In one implementation, the ventilation panel 213 includes a ventilation body 2131, a ventilation top plate 2133 and a ventilation bottom plate 2134 that are oppositely disposed, two ventilation side plates 2132, and a second bent portion 2135. A plurality of second ventilation holes 2137 are formed on the ventilation body 2131. The ventilation top plate 2133 and the ventilation bottom plate 2134 are disposed on a side of the ventilation body 2131. The ventilation top plate 2133 is connected to the upper part of the ventilation body 2131, and the ventilation bottom plate 2134 is connected to the lower part of the ventilation body 2131. Two ventilation side plates 2132 are arranged on a side surface of the ventilation body 2131, and the two ventilation side plates 2132 are respectively connected to the two sides of the ventilation body 2131. The second elastic component is disposed on at least one of the two ventilation side plates 2132. The second bent portion 2135 is connected to an end of the ventilation top plate 2133 facing away from the ventilation body 2131, and the second bent portion 2135 is located between the ventilation top plate 2133 and the ventilation bottom plate 2134.

Illustratively, the ventilation bottom plate 2134 and each ventilation side plate 2132 may all be perpendicular to the ventilation body 2131. The ventilation top plate 2133 is connected between the ventilation body 2131 and the second bent portion 2135. After installation, the working assembly 100 may abut against the second bent portion 2135, so that the air flowing through the first heat sink 123 and the second heat sink 124 can better flow into the electronic device 200 or flow out of the electronic device 200 through the second ventilation hole 2137, further improving the heat dissipation effect.

In one example, as shown in FIGS. 9A and 9B, the at least one second elastic component includes a plurality of second elastic clips 214 disposed at intervals along the second direction, and the second elastic clips 214 are pressed tightly between the ventilation panel 213 and the corresponding side wall of the housing 210.

For example, a plurality of spacing slots 2136 arranged at intervals vertically may be formed on the ventilation side plate 2132, and a portion of the ventilation side plate 2132 between two adjacent spacing slots 2136 is the second elastic clip 214. During installation, the two ventilation side plates 2132 are squeezed into the corresponding side walls of the housing 210. At this time, the plurality of second elastic clips 214 are elastically deformed. Then, the ventilation panel 213 is threadedly connected to the housing 210 via threaded fasteners. During disassembly, only the threaded fasteners need to be removed, and then the ventilation panel 213 is pulled out. At this time, the plurality of second elastic clips 214 return to their original state.

In another example, the above-mentioned at least one second elastic component includes a second conductive foam 215 extending along the second direction. With such a configuration, it is possible that while achieving a firm connection between the ventilation panel 213 and the housing 210, it also allows that the ventilation panel 213 and the housing 210 may be electrically connected via the second conductive foam 215, thereby providing effective shielding and grounding effect, further improving the safety of the electronic device 200.

In one implementation, at least one baffle is disposed on the top of the housing 210, and the baffle corresponds to the heat sink 120 in position. In this way, the air blown out by the fan module 222 may all be blown to a plurality of heat sinks 120, avoiding part of the air from blowing into the top housing 212 on the top of the housing 210, thereby increasing the ventilation volume in the heat-dissipating air duct, avoiding dust accumulation on the heat sink 120, and further improving the heat dissipation effect.

Specifically, the present invention provides an electronic device 200 including:

a housing 210, wherein a heat-dissipating air duct with an air inlet and an air outlet is defined within the housing 210, and at least one working assembly 100 is disposed in the heat-dissipating air duct; and a control board 260 disposed above the housing 210 and electrically connected to an upper end of the working assembly 100.

In the above solution, the air inlet and the air outlet are disposed on two opposite side surfaces of the housing 210, the control board 260 is arranged above the housing 210, and an electrical connection port is disposed at the upper end of the working assembly 100 to connect with the control board 260, so as to optimize the electrical connection structure between the control board 260 and the working assembly 100, so that the overall shape and layout of the electronic device 200 are compact and orderly. When the working assembly 100 is damaged, only the damaged working assembly 100 needs to be removed from one side. The control board 260 will not interfere with the working assembly 100, which facilitates the disassembly and installation of the entire electronic device 200 and improves the efficiency of servicing and replacement of the working assembly 100.

Optionally, the electronic device 10 further includes: at least one fan module 222 arranged on a side of the housing 210 in an arrangement direction of the air inlet and the air outlet; wherein at least one fan interface 262 is disposed on the control board 260, and the fan interface 262 is connected to the fan module 222.

In the above solution, the housing 210 is generally a cuboid structure, and the housing 210 may include a top surface, a bottom surface, and four side surfaces, and the four side surfaces are respectively connected between the top surface and the bottom surface. The fan assembly 220 may be arranged at one of the air inlet and the air outlet for air conduction and heat exchange, and the other of the air inlet and the air outlet is used for loading and unloading the working assembly 100. When the working assembly 100 is damaged, only the damaged working assembly 100 needs to be removed and taken out from the side where the fan assembly 220 is not arranged, without removing the fan assembly 220. The control board 260 is arranged above the housing 210 to control the operation of the fan module 222. The above arrangement facilitates the disassembly and installation of the electronic device 200 as a whole, and also facilitates improving the efficiency of servicing and replacement of the working assembly 100.

Optionally, the at least one fan interface 262 is disposed close to the fan module 222.

In the above solution, the fan module 222 may be disposed at the air inlet and the air outlet. When the fan module 222 is disposed at the air inlet, it is of the blowing type. At this time, when the control board 260 is disposed above the housing 210, it may also be disposed close to the air inlet. At this time, the fan interface 262 is also disposed close to the fan module 222 for easy electrical connection.

Optionally, the working assembly 100 includes a circuit board 110.

In the above solution, chips may be arranged on the circuit board 110 for data processing.

Optionally, the working assembly 100 includes a heat sink 120, and the heat sink 120 is disposed on at least a side of the circuit board 110.

In the above solution, circuits and chips of the circuit board 110 generate heat during operation, and the heat sink 120 dissipates heat from the circuit board 110.

Optionally, a first signal socket 112 is disposed on the circuit board 110, and a second signal socket 261 is disposed on the control board 260, and the first signal socket 112 is electrically connected to the second signal socket 261.

In the above solution, the control board 260 may provide control signals, working signals and other signals to the circuit board 110, and the circuit board 110 may feedback status signals, data signals and other signals to the control board 260. Illustratively, there are three second signal sockets 261. The three second signal sockets 261 may be connected one-to-one with the circuit boards 110 of the three working assemblies 100 through three first cables, so that the control board 260 can control the operation of the circuit board 110.

Optionally, the second signal socket 261 is disposed on a side of the control board 260 close to the first signal socket 112.

In the above solution, in a case where the fan module 222 is of the blowing type, the control board 260 may be disposed above the housing 210 and close to the air inlet, and the first signal socket 112 may be disposed above the working assembly 100 and close to the air outlet. At this time, the second signal socket 261 is disposed on a side of the control board 260 close to the air outlet to facilitate the electrical connection between the first signal socket 112 and the second signal socket 261.

Optionally, a power supply module 270 is disposed on a side of the housing 210, and the power supply module 270 is used to supply power to the working assembly 100 and the fan module 222; the control board 260 is provided with a power supply interface 265, which is connected to the power supply module 270.

In the above solution, the power supply module 270 supplies power to the control board 260 through the power supply interface 262. The power supply module 270 is disposed to keep clear of the air inlet and the air outlet. The power supply module 270 is arranged on the side surface to facilitate powering the fan assembly 220 and the working assembly 100.

Optionally, the power supply interface 265 is disposed on a side of the control board 260 close to the power supply module 270.

In the above solution, the power supply interface 265 is connected to the power supply module 270. Illustratively, the power supply module 270 is disposed on the left side surface of the housing 210, and the power supply interface is disposed on a position on the control board 260 close to the left side surface of the housing 210 to facilitate electrical connection between the power supply module 270 and the power supply interface.

Optionally, the working assembly 100 includes a circuit board 110, on which a first connection base 140 and a second connection base 150 are disposed; wherein the first connection base 140 includes a first connection portion 141 and a first connection base body 142. The first connection portion 141 is connected to the first connection base body 142. The first connection portion 141 is connected to the circuit board 110, and the first connection base body 142 is connected to the power supply module 270; the second connection base 150 includes a second connection portion 151 and a second connection base body 152, the second connection portion 151 is connected to the circuit board 110, and the second connection base body 152 is connected to the power supply module 270.

In the above solution, the power supply module 270 supplies power to the circuit board 110 through the first connection base 140 and the second connection base 150.

Optionally, a first through hole 1412 is provided on the first connection portion 141 and/or the second connection portion 151.

In the above solution, the first connection base 140 and the second connection base 150 are provided with a first through hole 1412, and the first through hole 1412 may be used for welding alignment. In addition, the first through hole 1412 provided on the first connection base 140 and the second connection base 150 is also conducive to venting gas when welding the first connection base 140 and the second connection base 150.

Optionally, it further includes: a first conductive connection member 280 connected between the first connection base body 142 and the power supply module 270; and a second conductive connection member 290 connected between the second connection base body 152 and the power supply module 270.

In the above solution, one part of the first conductive connection member 280 is electrically connected to the power supply module 270, and the other part of the first conductive connection member 280 is electrically connected to a first connection base 140 of the working assembly 100; one part of the second conductive connection member 290 is electrically connected to the power supply module 270, and the other part of the second conductive connection member 290 is electrically connected to a second connection base 150 of the working assembly 100.

Optionally, the first conductive connection member 280 includes a first circuit board connection portion 281 and a first power supply connection portion 282, the first circuit board connection portion 281 is connected to the first connection base body 142, and the first power supply connection portion 282 is connected to the power supply module 270; the second conductive connection member 290 includes a second circuit board connection portion 291 and a second power supply connection portion 292, the second circuit board connection portion 291 is connected to the second connection base body 152, and the second power supply connection portion 292 is connected to the power supply module 270.

In the above solution, the bottom surface of the first circuit board connection portion 281 may contact the top surfaces of the plurality of first connection base bodies 142, and the first fasteners are suitable for passing through the first circuit board connection portion 281 to connect with the corresponding first connection base bodies 142. The bottom surface of the second circuit board connection portion 291 may contact the top surfaces of the plurality of second connection base bodies 152, and the second fasteners are suitable for passing through the first circuit board connection portion 291 to connect with the corresponding second connection base bodies 152. The first circuit board connection portion 281 may be parallel to the second circuit board connection portion 291, and both extend along the third direction. The first conductive connection member 280 may be a positive electrode conductive bar, and the second conductive connection member 290 may be a negative electrode conductive bar.

Optionally, the first circuit board connection portion 281 and/or the second circuit board connection portion 291 extend in a direction that is perpendicular to a direction from the air inlet to the air outlet and perpendicular to a vertical direction.

In the above solution, the working assembly 100 is arranged along a third direction, and the above-mentioned other part of the first conductive connection member 280, namely the first circuit board connection portion 281, may be parallel to the above-mentioned other part of the second conductive connection member 290, namely the second circuit board connection portion 291, and both extend along the third direction and are correspondingly connected to the working assembly 100.

Optionally, the control board 260 is provided with an indicator light 264 thereon, which is located at an end of the control board close to a side of the air inlet or the air outlet.

In the above solution, the indicator light 264 is disposed at the end of the side of the control board 260, so that the indicator light 264 may be observed from a side of the electronic device 10, thereby avoiding the situation where the fan module 22 blocks the indicator light 264.

Optionally, a top housing 212 is disposed on the top of the housing 210, and the control board 260 is disposed within the top housing 212.

In the above solution, a control board 260 may be arranged within the top housing 212, and the control board 260 may be connected to the working assembly 100, the power supply module 270 and the fan assembly 220. A signal line may be provided between the control board 260 and the working assembly 100, and a power line may be provided between the power supply module 270 and the working assembly 100. The top housing 212 may be used to store the signal line and the power line to avoid cable leakage and protect the internal operating environment of the electronic device 200.

Optionally, the control board 260 is provided with a temperature sensor 263 thereon.

In the above solution, the temperature sensor 263 may be used to sense the temperature at the air inlet. In this way, a user may know the temperature at the air inlet or the air outlet in real time, avoid the temperature of the air entering from the air inlet or the air flowing in from the air outlet being too high, and endow the working assembly 100 with a better heat dissipation effect, thereby ensuring the normal operation of the working assembly 100 and effectively extending the service life of the entire electronic device 200.

Optionally, the temperature sensor 263 is disposed at the bottom of the control board 260, and the temperature sensor 263 is located within the top housing 212. The top surface of the housing 212 is formed with a ventilation hole 211 connected to the heat-dissipating air duct, and the ventilation hole 211 corresponds to the temperature sensor 263 in position.

In the above solution, the temperature sensor 263 may sense the temperature at the air inlet or air outlet through the ventilation hole 211. Moreover, the temperature sensor 263 may be hidden in the top housing 212 to prevent the temperature sensor 263 from direct contact with the external environment, so that the top housing 212 may effectively protect the temperature sensor 263 and prevent the temperature sensor 263 from being damaged, and may make the appearance of the electronic device 200 more neat and beautiful.

Optionally, the temperature sensor 263 is disposed on the top of the control board 260, and the temperature sensor 263 extends from a side surface of the top housing 212.

In the above solution, a passage hole may be formed on the side of the top housing 212 close to the air inlet or the air outlet, the temperature sensor 263 may be set on the side of the control board 260 close to the air inlet or the air outlet, and the temperature sensor 263 protrudes out of the top housing 212 from the passage hole. With such configuration, the temperature sensor 263 can directly protrude out of the top housing 212 to sense the temperature at the air inlet or the air outlet, and no holes need to be opened on the housing 210 and the mounting member 221, thereby making the structure of the housing 210 simpler and easier to process.

Optionally, a free end of the temperature sensor 263 passes through the top of the housing 210 and protrudes into the housing 210.

In the above solution, the free end of the temperature sensor 263 may pass through the top of the housing 210 and protrude into the housing 210 and be opposite to the fan assembly 220. In this way, in a case where the temperature sensor 263 is arranged close to the air inlet, the free end of the temperature sensor 263 can protrude into an air inlet cavity of the housing 210 to detect the temperature of the air input by the fan assembly 220 and can sense the temperature of the air inlet more accurately.

Optionally, the electronic device 10 further includes a mounting member 221, which is connected to the housing 210; and the fan module 222 is connected to a side of the mounting member 221 facing away from the housing.

In the above solution, the mounting member 221 and the fan module 222 constitute a fan assembly 220, the fan assembly 220 may be arranged at the air inlet or the air outlet, the outer contour size of the mounting member 221 is larger than the outer contour size of the fan module 222. The mounting member 221 is provided as a transition mounting member at the air inlet or outlet of the housing 210 to facilitate the fixed installation of the fan module 222 on the housing 210. A plurality of first ventilation holes 2220 are formed on the portion of the mounting member 221 opposite to the fan module 222. When the fan module 222 is of the blowing type and the fan module 222 is operating, external air enters the heat-dissipating air duct through the plurality of first ventilation holes 2220 under the action of the fan module 222, exchanges heat with the first heat sink 123 and the second heat sink 124, and then flows out from the air outlet. When the fan module 222 is of suction type and the fan module 222 is operating, external air enters the heat-dissipating air duct through the plurality of second ventilation holes 2137 under the action of the fan module 222, exchanges heat with the first heat 123 and the second heat 124, and then flows out from the plurality of first ventilation holes 2220.

Optionally, there are two fan modules arranged in a vertical direction 222.

In the above solution, the height of the housing 210 is larger than the length, and there are two fan modules 222 arranged in a vertical direction, and the ventilation area covers the working assembly 100. Of course, for the arrangement of the fan modules 222, other numbers and specifications may be selected based on the size of the housing 210.

Optionally, the vertically arranged two fan modules 222 constitute a fan group, and a plurality of fan groups are provided in a direction from the air inlet to the air outlet.

In the above solution, in order to increase the heat dissipation effect, a plurality of layers of fan groups are arranged, wherein the preferred solution may arrange one layer of fan groups or two layers of fan groups.

Optionally, first mounting portions are disposed at four corners of the fan module 222, second mounting portions are provided on the mounting member 221, and fasteners respectively pass through the first mounting portions to be connected to corresponding second mounting portions.

In the above solution, the fan module 222 and the mounting member 221 may be fastened and connected through corresponding mounting portions, and of course, they may also be connected by bonding. The mounting member 221 may firmly fix the fan module 222 on the housing 210, thereby improving the structural stability and reliability of the entire electronic device 200. The plurality of fan modules 222 can increase the ventilation volume of the heat-dissipating air duct, reduce air resistance, and inhibit the deposition of dust on the heat sink 120, thereby effectively improving the heat dissipation effect of the working assembly 100.

Optionally, the first mounting portions are through holes, the second mounting portions are threaded holes, and the fasteners are threaded fasteners.

In the above solution, the threaded fasteners pass through the through holes of the fan module and are threadedly connected to corresponding threaded holes, thereby achieving a fixed connection between the fan module 222 and the mounting member 221.

Optionally, a flexible protective cover 250 is provided on a side of the fan module 222 facing away from the mounting member 221. The flexible protective cover 250 is sleeved on an outer periphery of the fan module 222.

In the above solution, the flexible protective cover 250 configured in this way can effectively protecting the edges and corners of the fan module 222, thus preventing the fan module 222 from being worn, and it may prevent the edges and corners of the fan module 222 from scratching workers, thereby improving safety. Optionally, the material of the flexible protective cover 250 may be made of soft rubber but is not limited thereto.

In the description of the present specification, it can be appreciated that orientations or positional relationships indicated by terms such as “central”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like are orientations or positional relationships based on the drawings, which are only for the convenience of describing the present application and simplifying the description, and do not indicate or imply that the referred device or element must have a specific orientation, be constructed and operated in a specific orientation, and therefore should not be understood as a limitation on the present application.

In addition, terms such as “first” and “second” are used for descriptive purposes only and cannot be understood as indicating or implying relative importance or implicitly indicating the quantity of the indicated technical features. Therefore, a feature defined as “first” or “second” may explicitly or implicitly include one or more of the features.

In the present application, unless otherwise clearly specified and limited, terms such as “mount”, “link”, “connect”, “fix”, etc. and variants thereof should be understood in a broad sense. For example, it may be a fixed connection, or may be a detachable connection, or formed into one piece. It may be a mechanical connection, an electrical connection, or a communication connection. It may be a direct connection or an indirect connection through an intermediate medium. It may be an internal communication between two elements or an interaction relationship between two elements. For those of ordinary skill in the art, the specific meanings of the above terms in the present application may be understood according to specific circumstances.

In the present application, unless otherwise clearly specified and limited, a first feature being “on” or “under” a second feature may include the first and second features being in direct contact, or may include the first and second features not being in direct contact but being in contact through another feature between them. Moreover, a first feature being “over”, “above”, or “onto” a second feature includes the first feature being directly above or obliquely above the second feature, or simply means that the first feature is at a higher horizontal level than the second feature. A first feature being “under”, “below”, or “beneath” a second feature includes the first feature being directly below or diagonally below the second feature, or simply means that the first feature is at a lower horizontal level than the second feature.

The above disclosure provides many different embodiments or examples for implementing different structures of the present application. In order to simplify the disclosure of the present application, components and arrangements of specific examples are described above. Of course, they are merely examples and are not intended to limit the present application. In addition, the present application may repeat reference numerals and/or reference letters in different examples. Such repetition is for the purpose of simplicity and clarity, which is not aimed to indicate relationships between various embodiments and/or arrangements discussed.

The above are only detailed description of the present application, the protection scope of the present application is not limited thereto. Any technician familiar with the technical field may easily conceive of various changes or substitutions within the technical scope disclosed in the present application, which should all be encompassed in the protection scope of the present application. Therefore, the protection scope of the present application should be based on the protection scope of the claims.

1. An electronic device, comprising:
a housing, wherein a heat-dissipating air duct with an air inlet and an air outlet is defined within the housing, and at least one working assembly is disposed in the heat-dissipating air duct; and
a control board disposed above the housing and electrically connected to an upper end of the working assembly.

2. The electronic device as claimed in claim 1, further comprising: at least one fan module arranged on a side of the housing in an arrangement direction of the air inlet and the air outlet; at least one fan interface is disposed on the control board, and the fan interface is connected to the fan module.

3. The electronic device as claimed in claim 2, wherein the at least one fan interface is disposed close to the fan module.

4. The electronic device as claimed in claim 1, wherein the working assembly comprises a circuit board.

5. The electronic device as claimed in claim 4, wherein the working assembly comprises a heat sink, which is disposed on at least a side of the circuit board.

6. The electronic device as claimed in claim 4, wherein a first signal socket is provided on the circuit board, a second signal socket is provided on the control board, and the first signal socket is electrically connected to the second signal socket;
wherein the second signal socket is arranged on a side of the control board close to the first signal socket.

7. (canceled)

8. The electronic device as claimed in claim 1, further comprising: a power supply module disposed on a side of the housing and configured to supply power to the working assembly;
a power supply interface is disposed on the control board, and the power supply interface is connected to the power supply module.

9. The electronic device as claimed in claim 8, wherein the power supply interface is disposed on a side of the control board close to the power supply module.

10. The electronic device as claimed in claim 8, wherein the working assembly comprises a circuit board, on which a first connection base and a second connection base are disposed; wherein
the first connection base comprises a first connection portion connected to the circuit board and a first connection base body connected to the power supply module;
the second connection base comprises a second connection portion connected to the circuit board and a second connection base body connected to the power supply module; and
wherein a through hole is provided on the first connection portion and/or the second connection portion.

11. (canceled)

12. The electronic device as claimed in claim 10, further comprising:
a first conductive connection member connected between the first connection base body and the power supply module; and
a second conductive connection member connected between the second connection base body and the power supply module.

13. The electronic device as claimed in claim 12, wherein:
the first conductive connection member comprises a first circuit board connection portion connected to the first connection base body and a first power supply connection portion connected to the power supply module; and
the second conductive connection member comprises a second circuit board connection portion connected to the second connection base body and a second power supply connection portion connected to the power supply module;
wherein the first circuit board connection portion and/or the second circuit board connection portion extend in a direction that is perpendicular to a direction from the air inlet to the air outlet and perpendicular to a vertical direction.

14. (canceled)

15. The electronic device as claimed in claim 1, wherein an indicator light is disposed on the control board, and the indicator light is located at an end of the control board close to a side of the air inlet or the air outlet.

16. The electronic device as claimed in claim 1, wherein a top housing is disposed on the top of the housing, and the control board is disposed in the top housing;
wherein a temperature sensor is disposed on the control board.

17. (canceled)

18. The electronic device as claimed in claim 16, wherein the temperature sensor is disposed at the bottom of the control board and is located within the top housing, a ventilation hole in communication with the heat-dissipating air duct is formed on a top surface of the housing, and the ventilation hole corresponds to the temperature sensor in position.

19. The electronic device as claimed in claim 16, wherein the temperature sensor is disposed on the top of the control board, and the temperature sensor protrudes from a side surface of the top housing.

20. The electronic device as claimed in claim 16, wherein a free end of the temperature sensor passes through the top of the housing and protrudes into the housing.

21. The electronic device as claimed in claim 2, further comprising a mounting member connected to the housing;
the fan module is connected to a side of the mounting member facing away from the housing.

22. The electronic device as claimed in claim 21, wherein there are two fan modules arranged in a vertical direction;
wherein the two fan modules arranged in the vertical direction constitute a fan group, and there are a plurality of fan groups disposed in a direction from the air inlet to the air outlet.

23. (canceled)

24. The electronic device as claimed in claim 21, wherein first mounting portions are disposed at four corners of the fan module, second mounting portions are provided on the mounting member, and fasteners respectively pass through the first mounting portions to be connected to corresponding second mounting portions;
wherein the first mounting portions are through holes, the second mounting portions are threaded holes, and the fasteners are threaded fasteners.

25. (canceled)

26. The electronic device as claimed in claim 21, wherein a flexible protective cover is provided on a side of the fan module facing away from the mounting member, and the flexible protective cover is sleeved on an outer periphery of the fan module.
